(19) United States
(12) Patent Application Publication
(10) Pub. No.: US 2025/0040120 A1
(43) Pub. Date: Jan. 30, 2025

(54) MICROELECTRONIC DEVICES, AND RELATED MEMORY DEVICES, AND ELECTRONIC SYSTEMS

(71) Applicant: MicronTechnology, Inc., Boise, ID (US)

(72) Inventors: Fatma Arzum Simsek-Ege, Boise, ID (US); Diem Thy Ngu Uyen Tran, Garden City, ID (US)

(21) Appl. No.: 18/754,652

(22) Filed: Jun. 26, 2024

Related U.S. Application Data
(60) Provisional application No. 63/516,076, filed on Jul. 27, 2023.

(51) Int. Cl. H10B 12/00

(52) U.S. Cl. CPC H10B 12/30; H10B 12/03; H10B 12/05

(57) ABSTRACT

A microelectronic device comprises a memory array region comprising vertical stacks of dynamic random access memory (DRAM) cells, each of the DRAM cells comprising a storage device of a vertical stack of storage devices and a horizontally neighboring access device of a vertical stack of access devices, and a staircase region substantially horizontally neighboring the memory array region in a first horizontal direction. The staircase region comprises a vertical stack of first conductive structures horizontally extending through the staircase region in the first horizontal direction, the first conductive structures in contact with the first DRAM cells and the second DRAM cells, and sub-staircase structures individually comprising second conductive structures in contact with the first conductive structures and horizontally extending from the first conductive structures in a second horizontal direction substantially perpendicular to the first horizontal direction, each of the sub-staircase structures individually comprising at least four steps, each step defined at horizontal boundaries of the second conductive structure defining the step. Related memory devices and electronic systems are also described.

### CROSS-REFERENCE TO RELATED APPLICATION

This application claims the benefit under 35 U.S.C. § 119 (e) of U.S. Provisional Patent Application Ser. No. 63/516,076, filed Jul. 27, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices including a staircase structure horizontally neighboring a memory array region, the staircase structure operatively associated with vertically stacked memory cells of the memory array region, and to related memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

As the size of the memory cells has decreased, the density and complexity of the memory array have increased. With the increased density of memory cells within the memory array, the density of the conductive interconnect structures configured to facilitate operation of the memory cells has also increased. For example, the spacing between neighboring conductive interconnect structures has decreased with the increased density of memory cells of the memory array. However, the increased density of the conductive interconnect structures presents difficulties in adequately forming conductive interconnect structures in electrical communication with the memory cells. In addition, as the density of memory cells has increased, the amount of area occupied by electrical interconnects between components of the memory cells has increased.

### BRIEF DESCRIPTION OF THE DRAWINGS

FIG. 1A through FIG. 1X are simplified, partial top-down view (FIG. 1A, FIG. 1D, FIG. 1G, FIG. 1I, FIG. 1L, FIG. 1O, FIG. 1S, and FIG. 1W) and simplified, partial cross-sectional views (FIG. 1B, FIG. 1C, FIG. 1E, FIG. 1F, FIG. 1H, FIG. 1J, FIG. 1K, FIG. 1M, FIG. 1N, FIG. 1P through FIG. 1R, FIG. 1T through FIG. 1V, and FIG. 1X) illustrating a method of forming a microelectronic device, in accordance with embodiments of the disclosure;

FIG. 2 is a block diagram of an electronic system, in accordance with embodiments of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device, such as DRAM memory device), apparatus, memory device, or electronic system, or a complete microelectronic device, apparatus, memory device, or electronic system including conductive contact structures. The structures described below do not form a complete microelectronic device, apparatus, memory device, or electronic system. Only those process acts and structures necessary to understand the embodiments described herein are described in detail below. Additional acts to form a complete microelectronic device, apparatus, memory device, or electronic system from the structures may be performed by conventional techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional clement (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth.

According to embodiments described herein, a microelectronic device includes a microelectronic device structure including array regions, each array region comprising vertical stacks of memory cells and vertical stack structures comprising vertically spaced conductive structures horizontally extending through the array region. The vertical stacks of memory cells individually comprise a vertical stack of storage devices, each storage device in contact with an access device of a vertical stack of access devices. The vertical stack structures individually horizontally extend from a first array region, through a staircase region, and to a second array region. The staircase region horizontally intervenes between the first array region and the second array region. The staircase region includes staircase structures shared between the vertical stacks of memory cells of the first array region and the vertical stacks of memory cells of the second array region. Each staircase structure individually comprises a vertical stack of vertically spaced first conductive structures horizontally extending through the first array region, the staircase region, and the second array region. In use and operation (e.g., responsive to an applied voltage) the first conductive structures are configured to be in electrical communication with the vertical stacks of memory cells of the first array region and the vertical stacks of memory cells of the second array region (e.g., the vertical stacks of access devices of the first array region and the vertical stacks of access devices of the second array region). Each staircase structure further comprises sub-staircase structures horizontally extending from the vertical stack of first conductive structures (e.g., substantially perpendicular to the vertical stack of first conductive structures). The sub-staircase structures comprise second conductive structures in contact with (and configured to be in electrical communication with, such as during use and operation) the first conductive structures. Each sub-staircase structure comprises steps defined at horizontal edges of the second conductive structures. The steps of each sub-staircase structure of a staircase structure are vertically offset from one another. In some embodiments, each sub-staircase structure individually comprises at least three steps, such as four steps. In some embodiments, regions horizontally between the staircase region and each of the first array region and the second array region comprise conductive routing regions configured to rout electrically conductive interconnections between the staircase region and additional circuity (e.g., circuitry, such as sub-word line driver circuitry, of an additional microelectronic device structure).

Conductive contact structures are in contact with the second conductive structures at the steps. The conductive contact structures individually contact the second conductive structures along horizontally extending surfaces thereof. In some embodiments, the conductive contact structures further individually contact the second conductive structures in a vertical direction. Contacting the second conductive structures in the horizontal direction and in the vertical direction increases a surface area of contact between the conductive contact structures and the second conductive structures, reducing the resistivity of the interconnections between the conductive contact structures and the second conductive structures and reducing the resistance-capacitance (RC) product (also referred as the “RC delay”) of the conductive contact structures, increasing the operation of circuitry (e.g., sub-word line drivers) in operably communication with the conductive contact structures.

The location of the staircase region horizontally between the first array region and the second array region reduces a horizontal area occupied by the staircase structures and facilitates increasing a density of the vertical stacks of memory cells within a given area. In addition, contacting the second conductive structures in the horizontal direction and the vertical direction facilitates increasing a number of steps of each sub-staircase structure, increasing the density of the steps, without increasing the resistivity of the conductive contact structures. In addition, forming the staircase structures to include the sub-staircase structures reduces the complexity of forming the steps, such as by reducing the quantity of different material compositions that are removed during patterning of the staircase structure compared to conventional microelectronic devices.

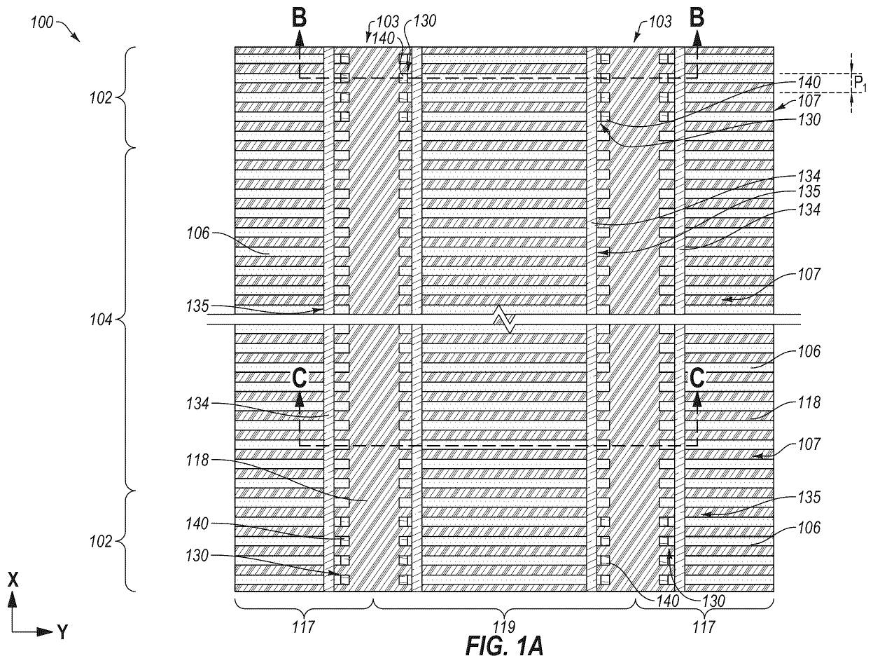

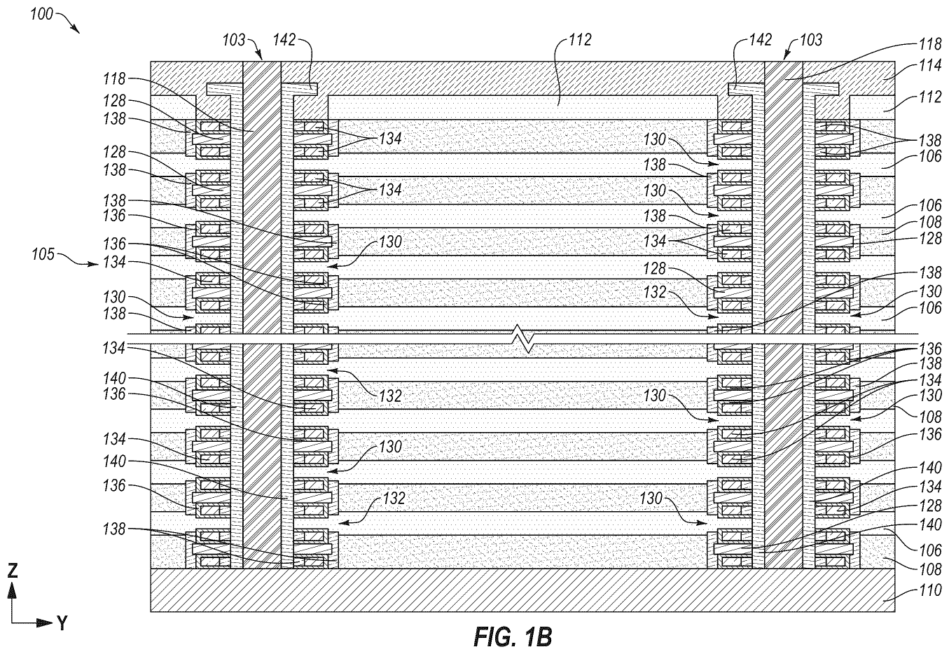

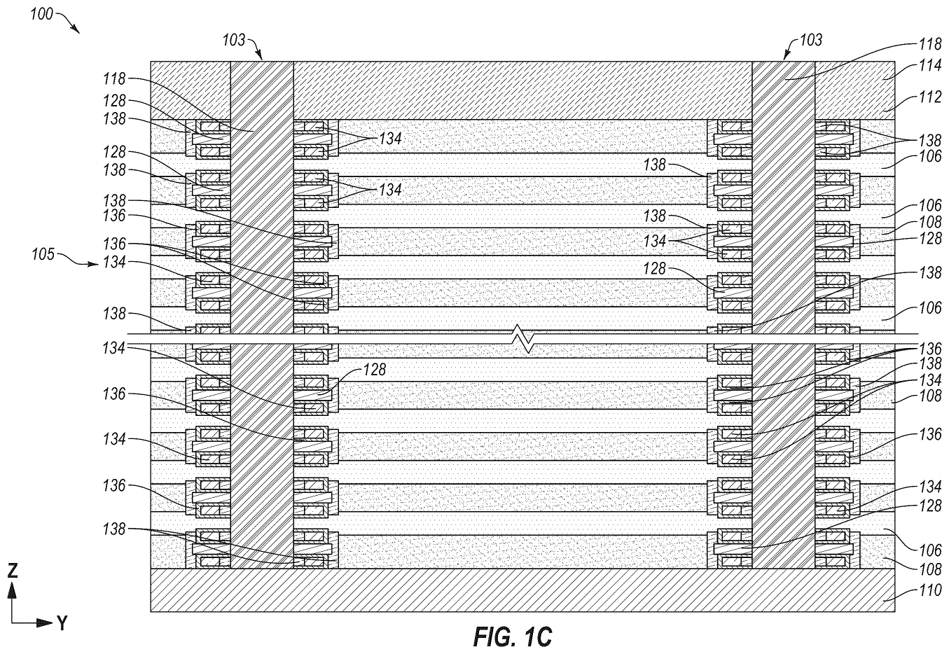

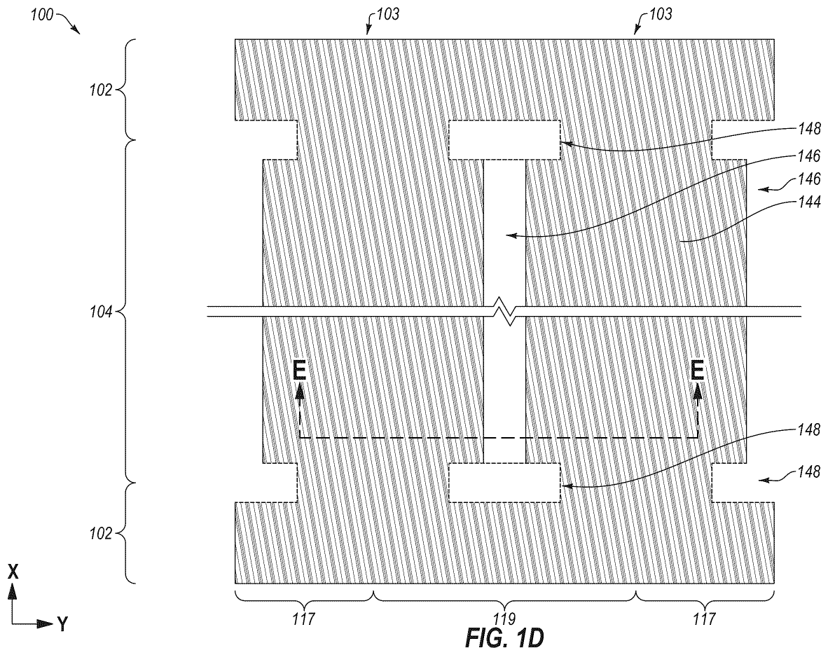

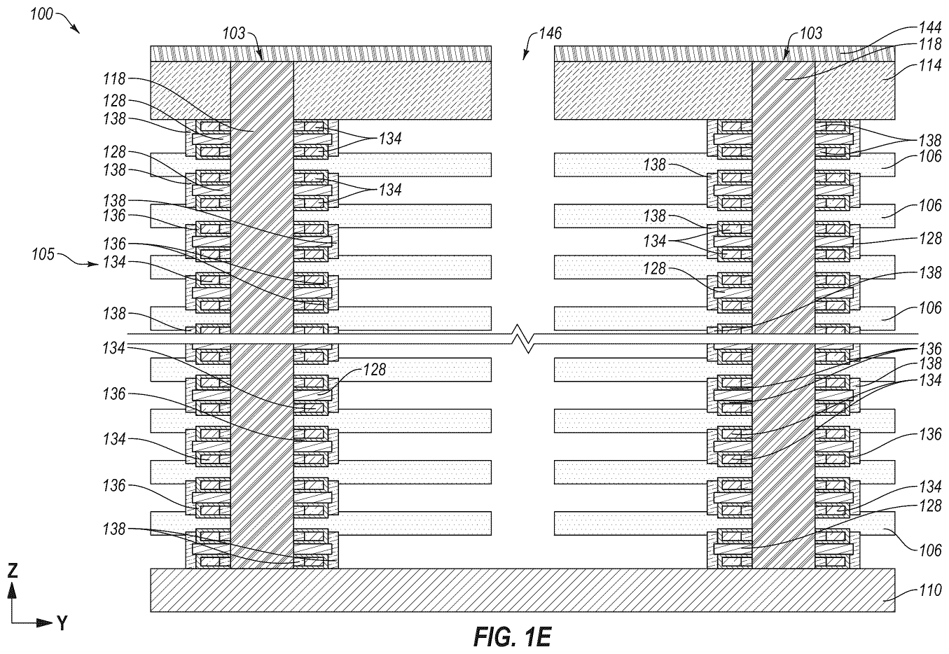

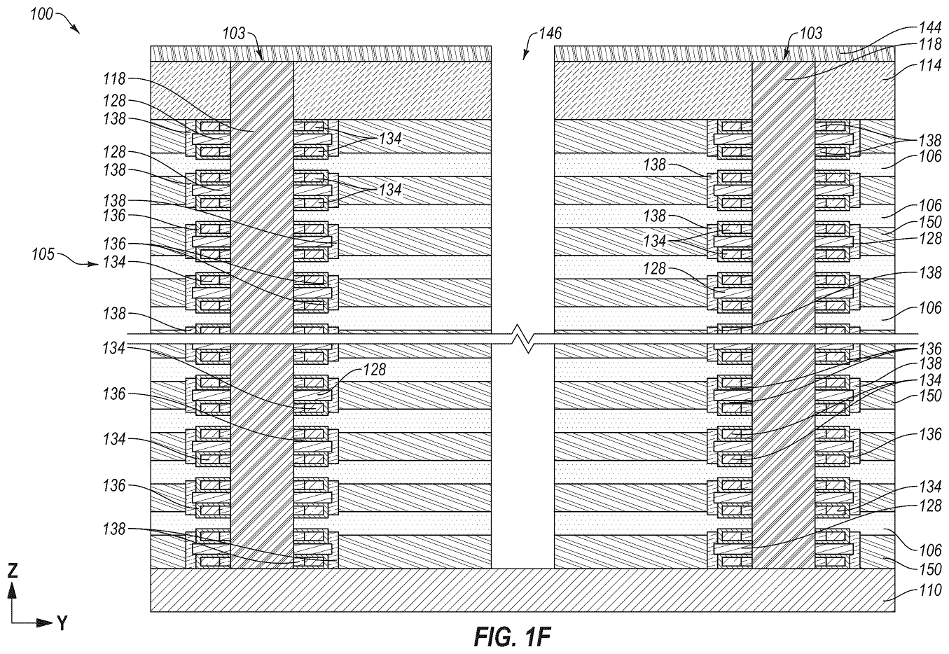

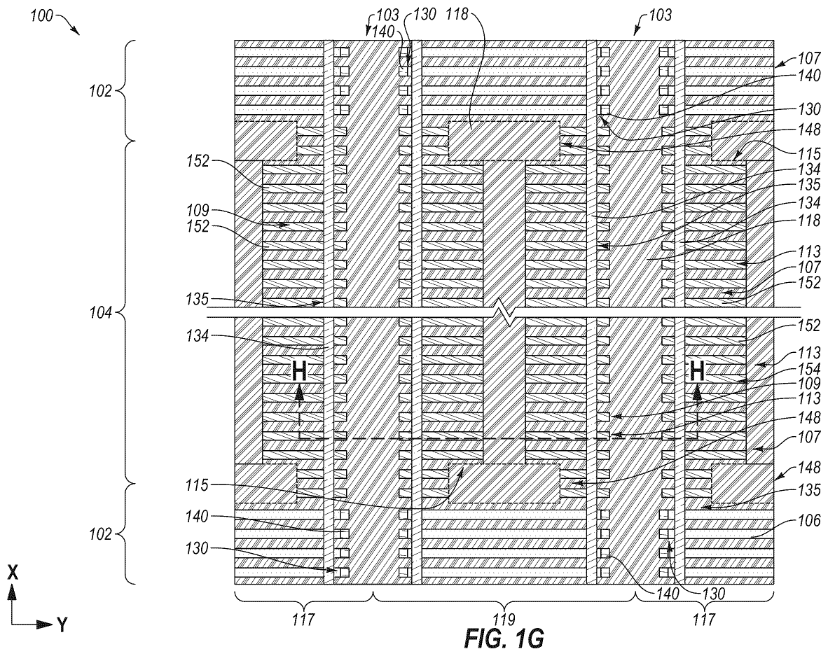

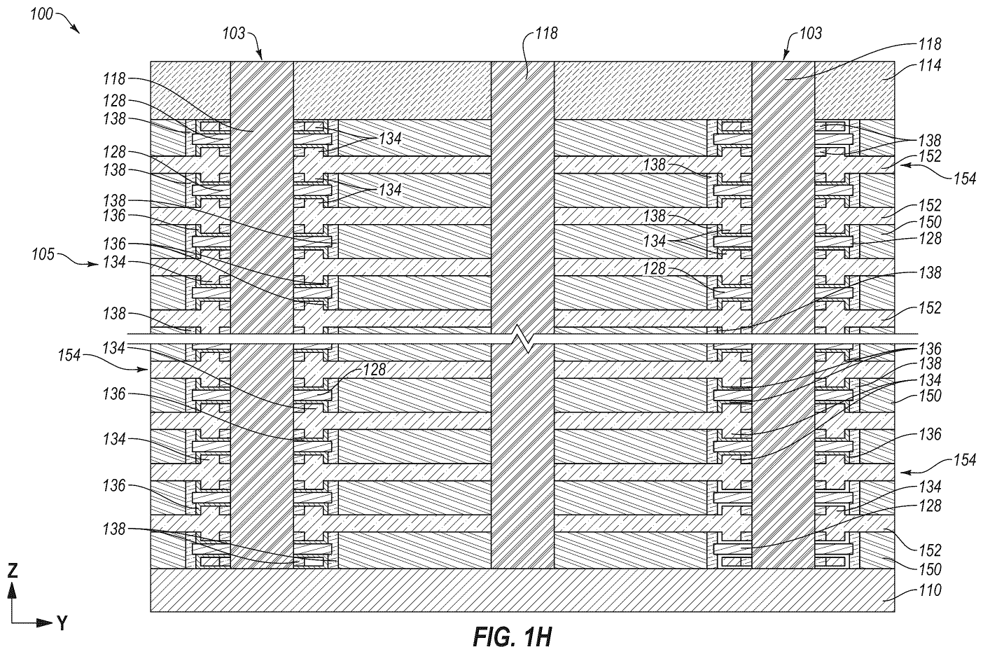

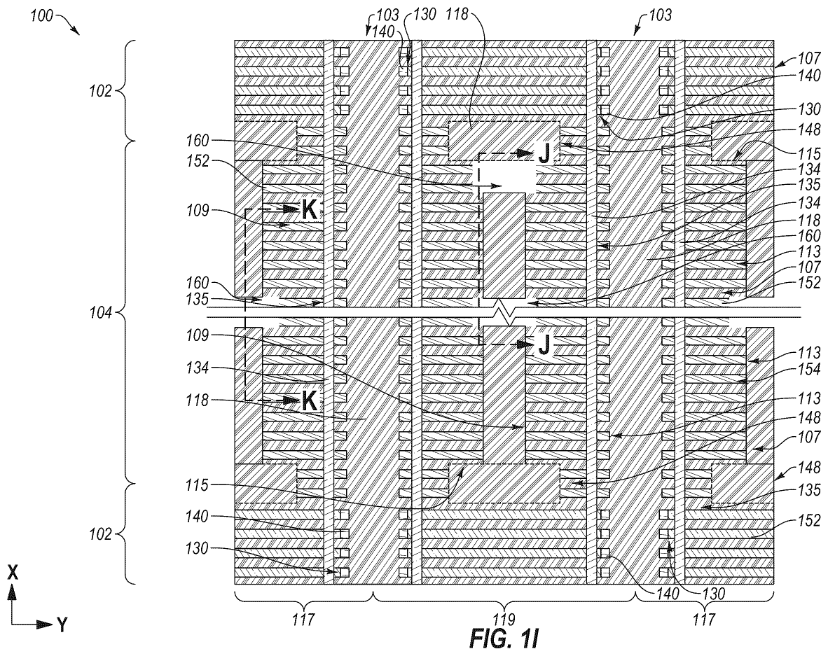

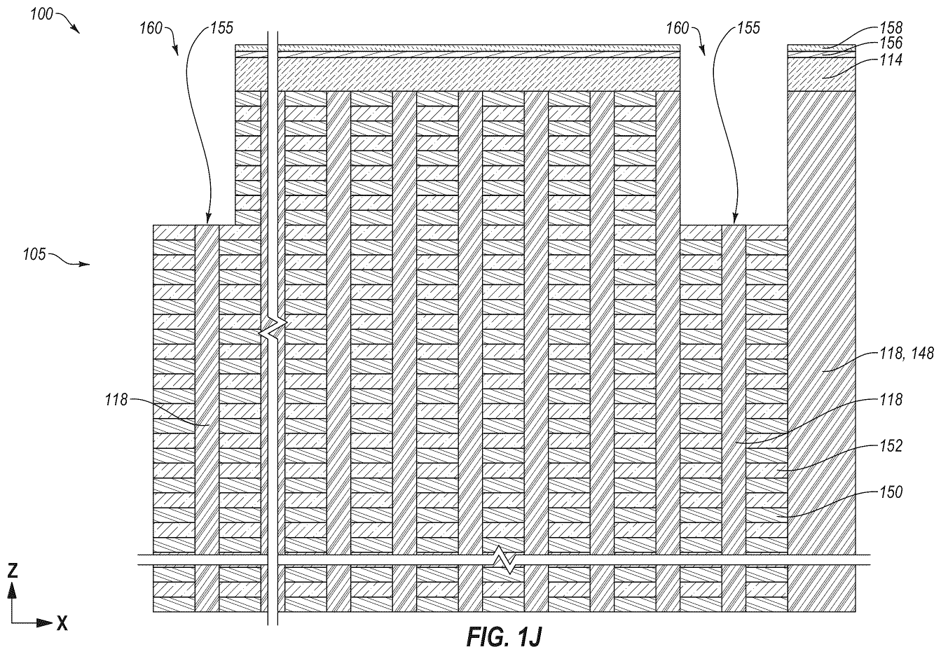

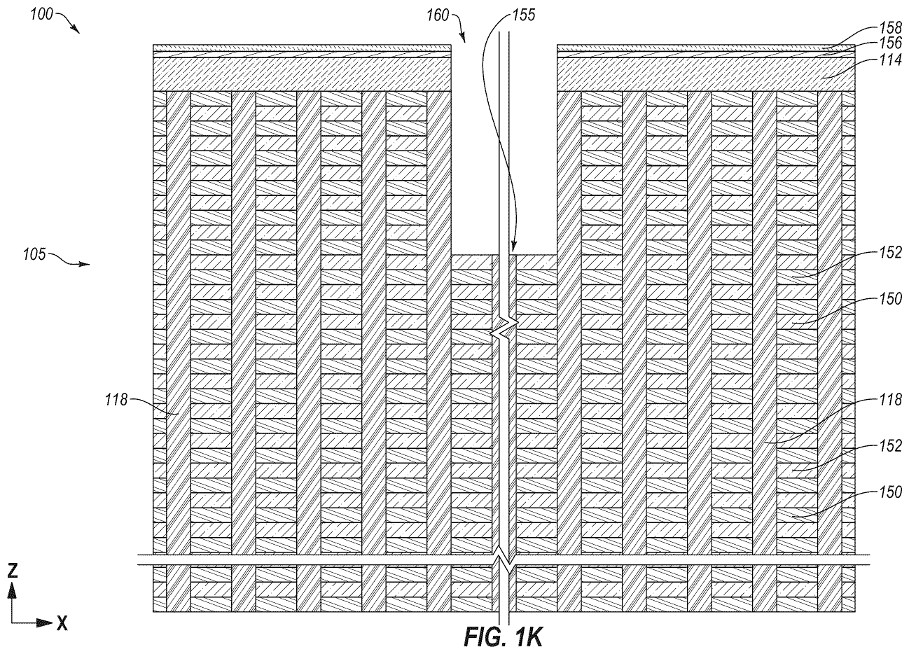

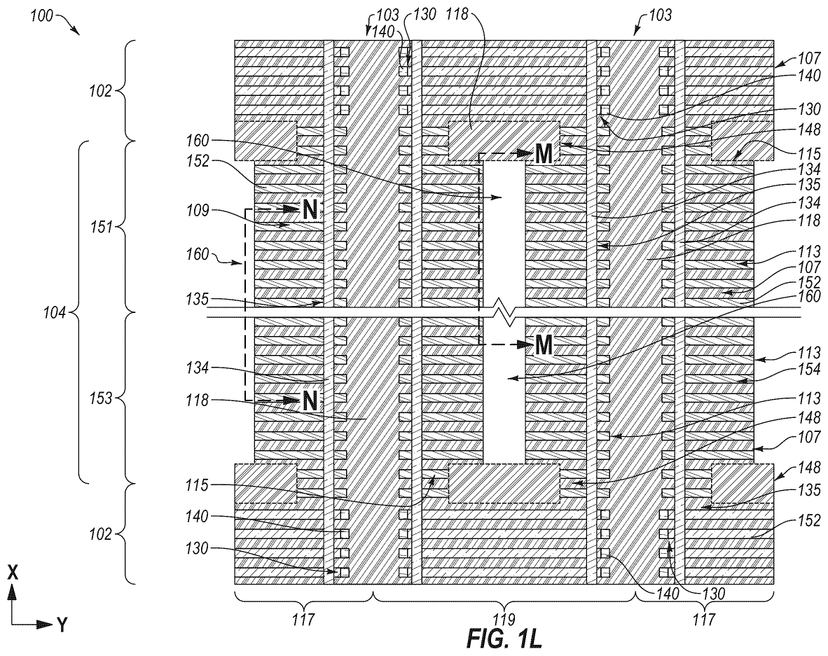

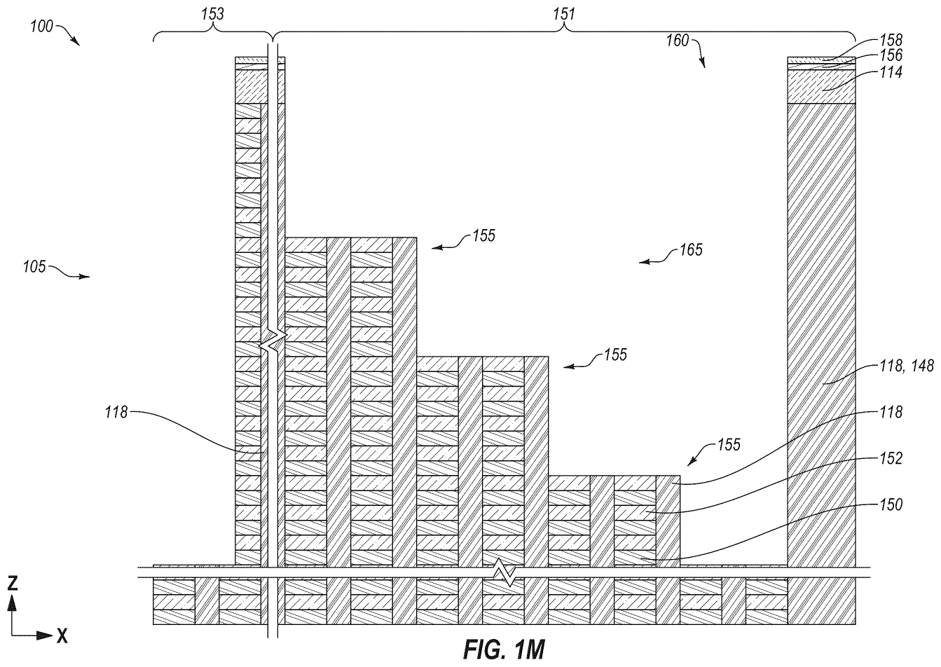

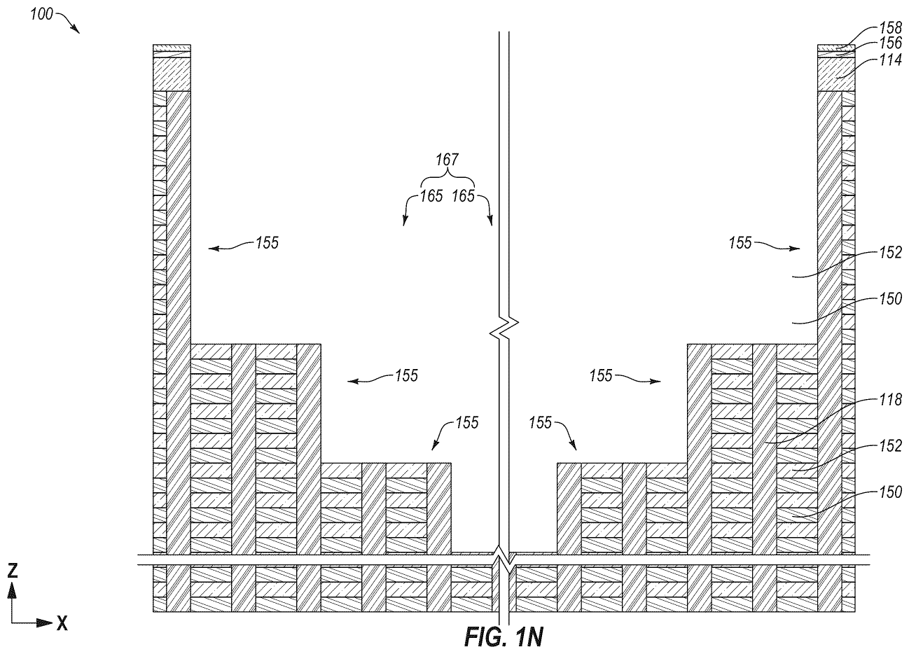

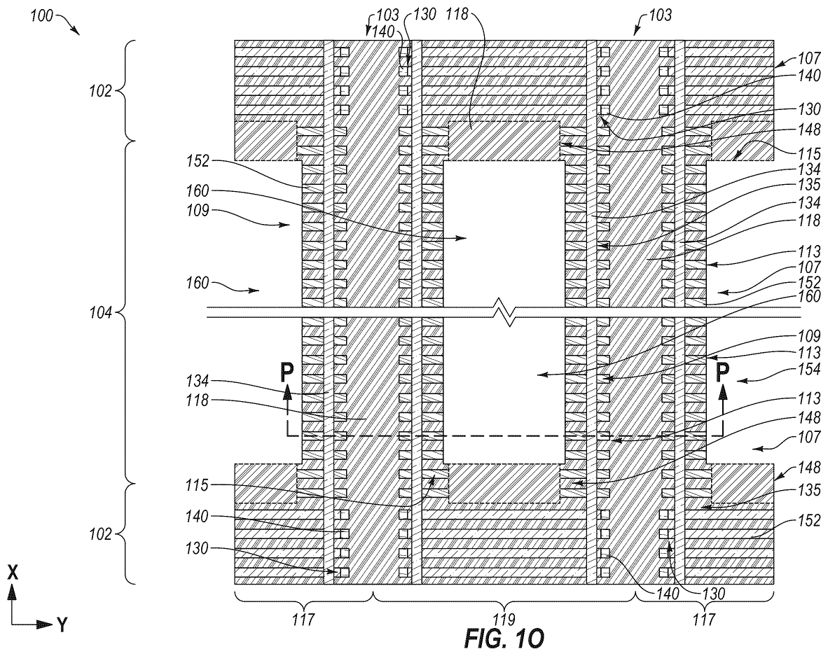

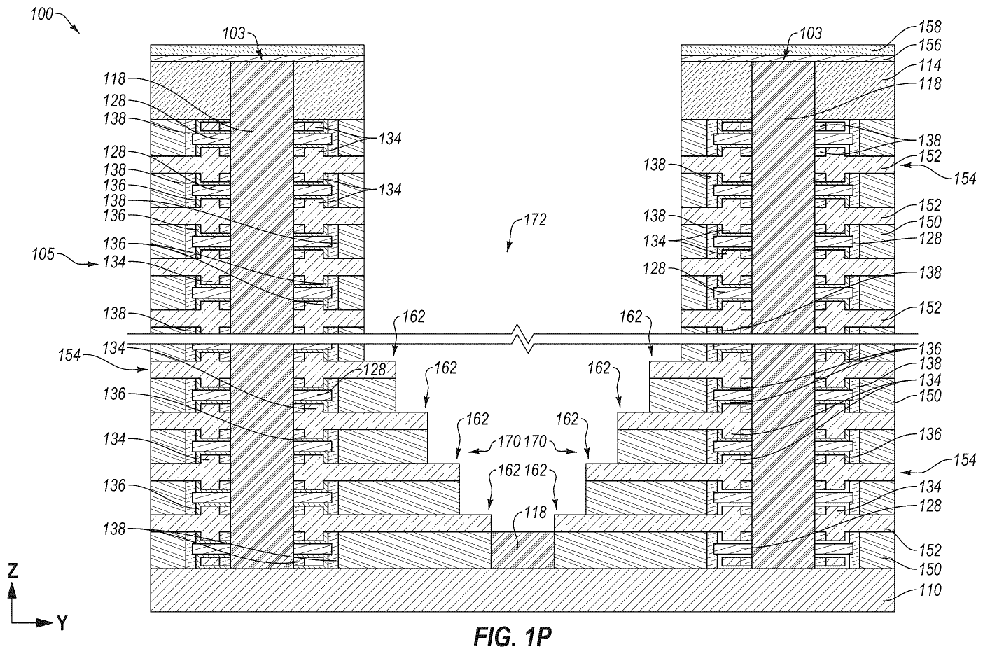

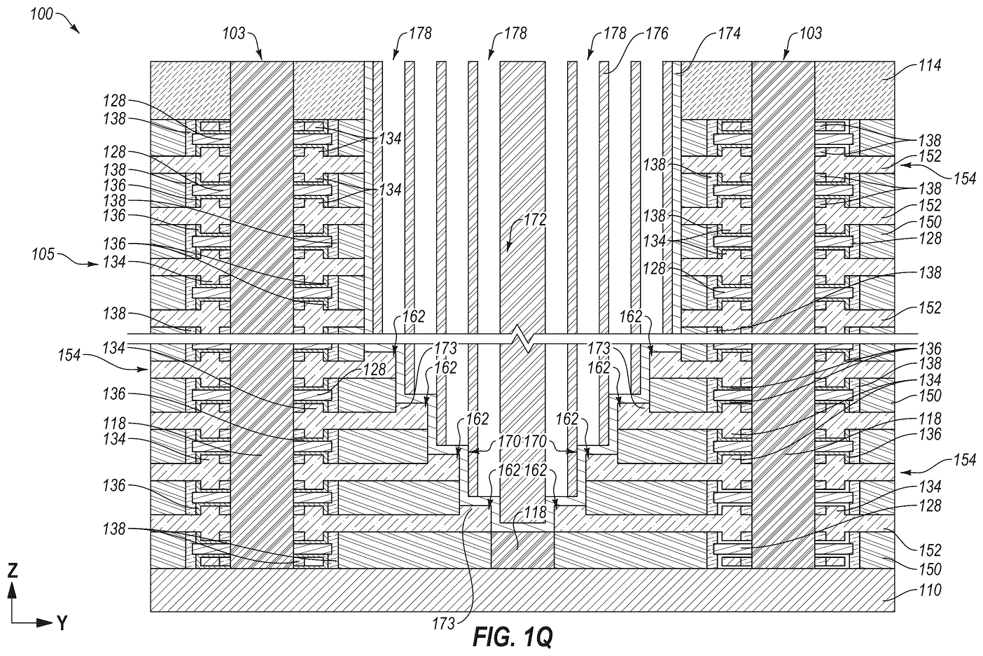

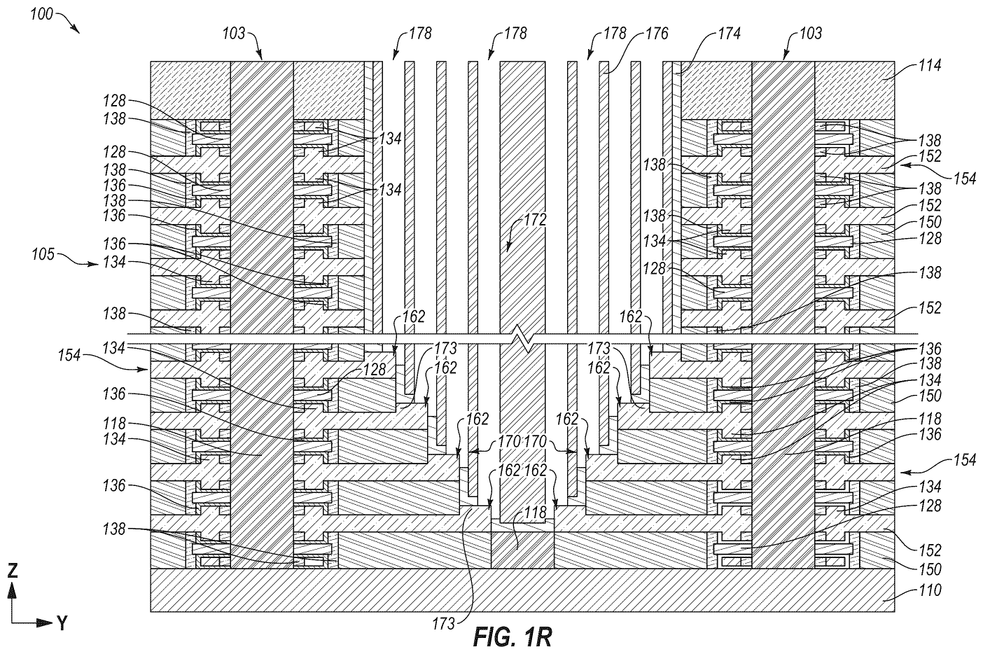

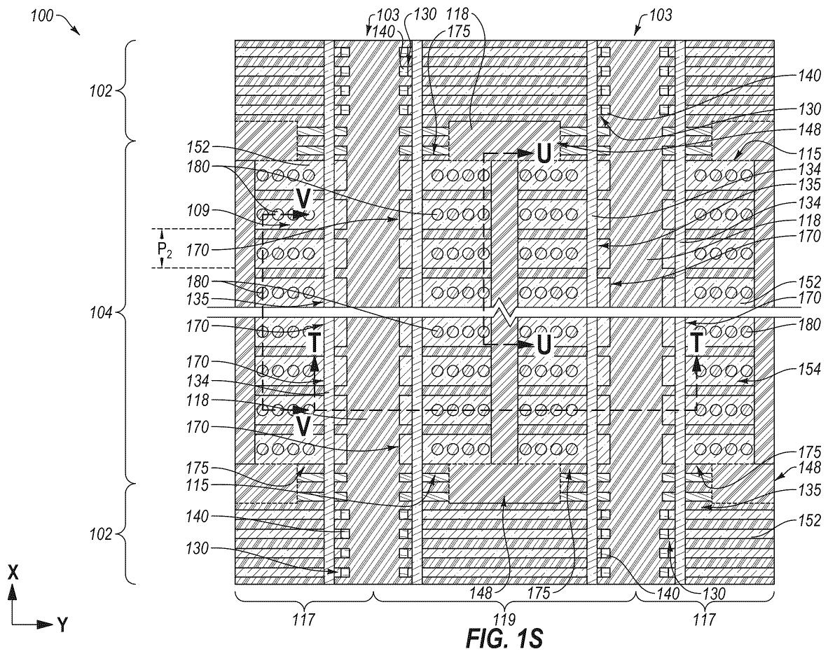

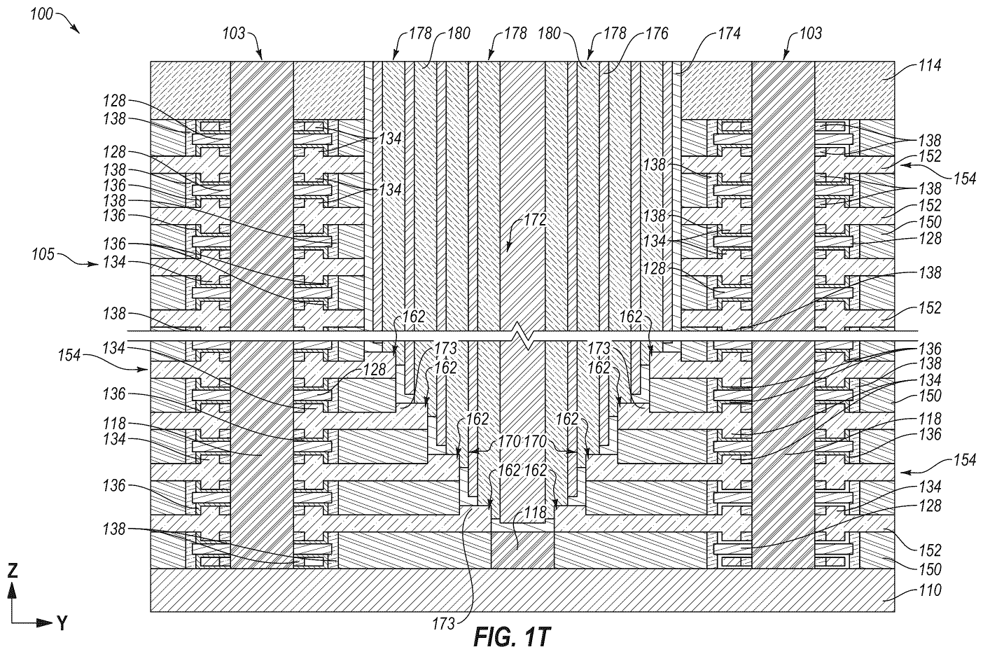

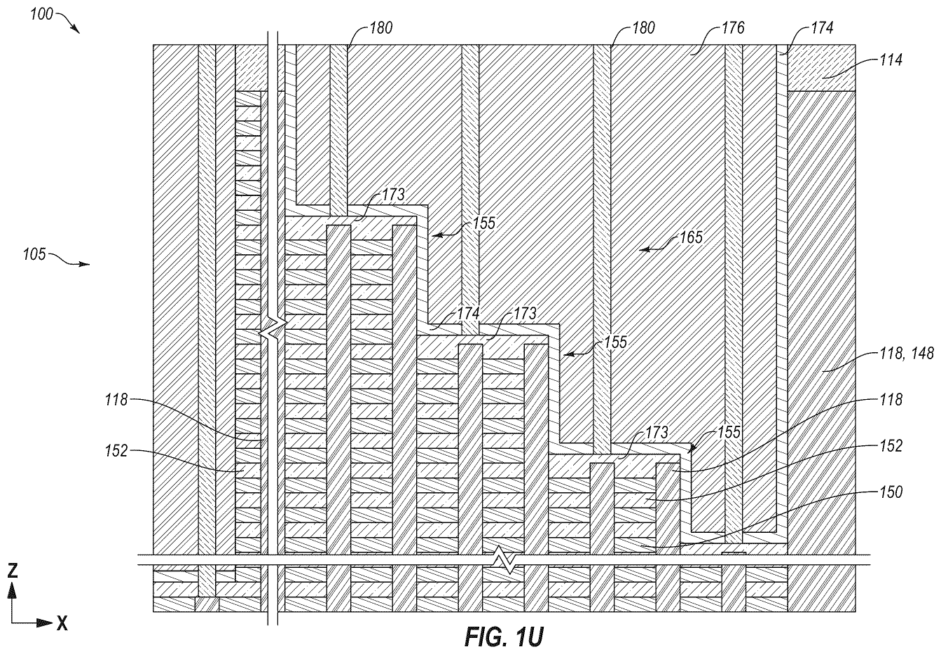

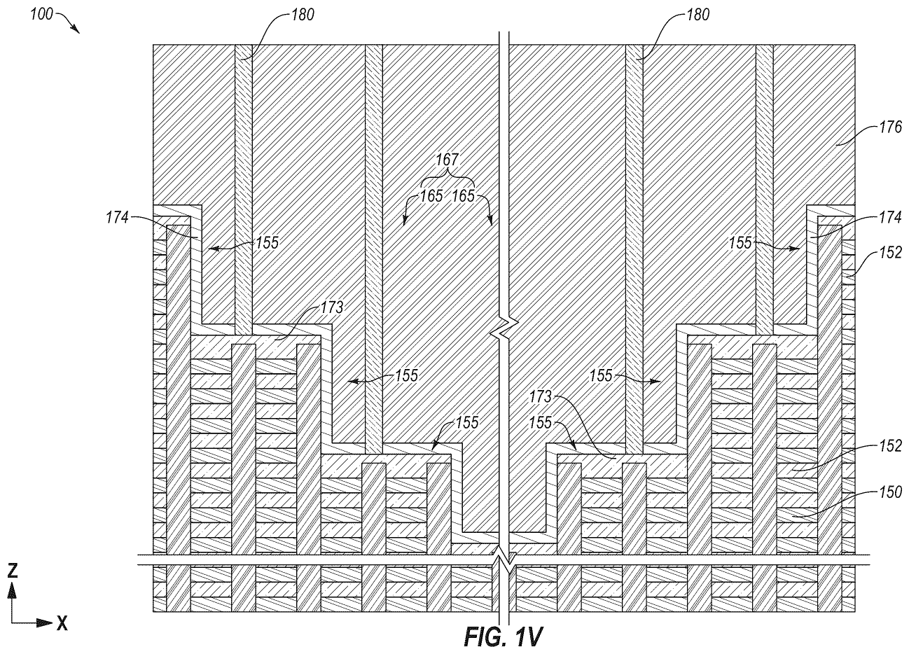

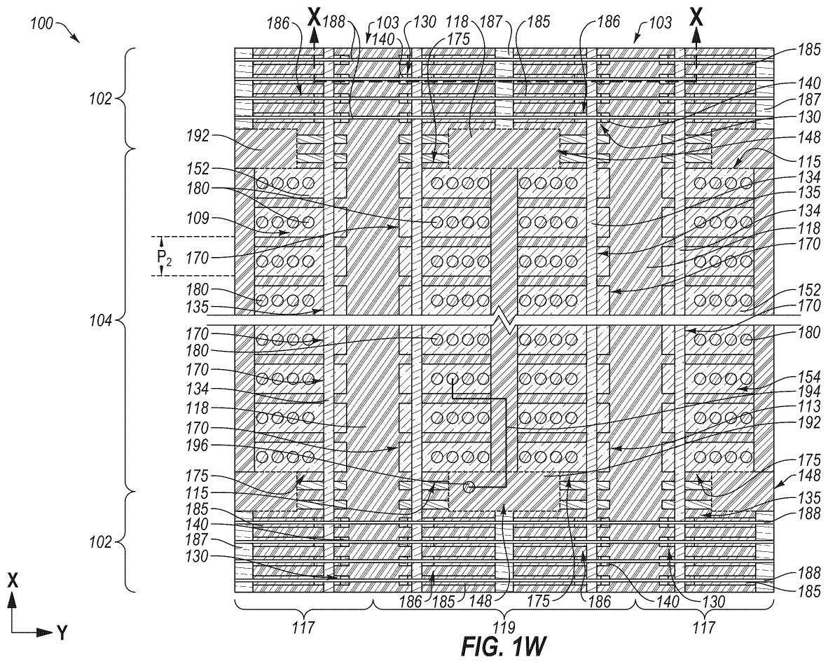

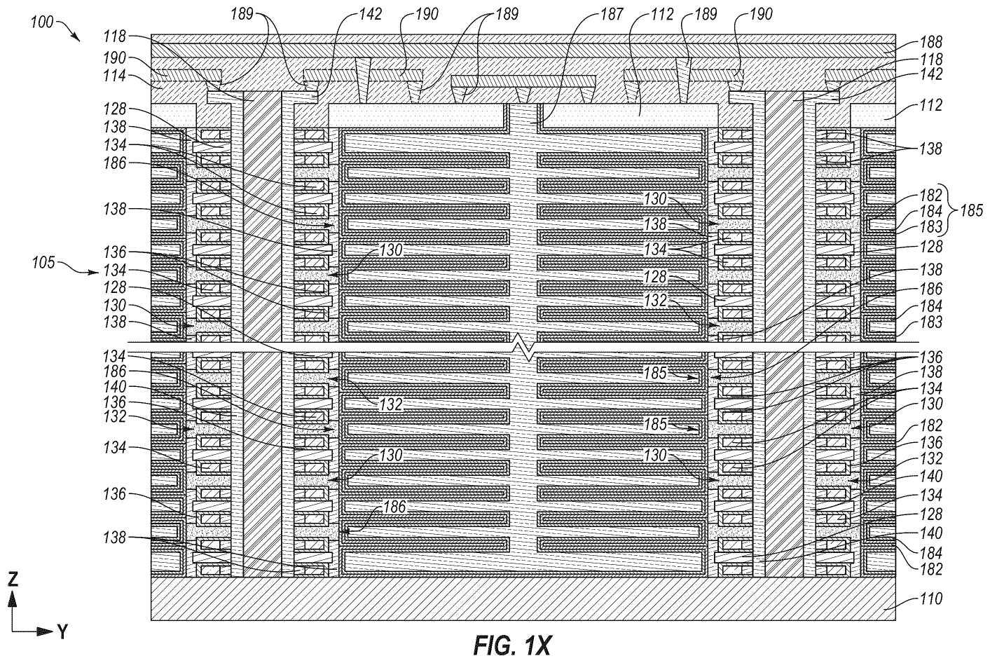

FIG. 1A through FIG. 1X are various views (described in further detail below) illustrating a microelectronic device at different processing stages of a method of forming a microelectronic device (e.g., a memory device, such as a 3D DRAM memory device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device.

FIG. 1A is a simplified partial top-down view of a microelectronic device 100; FIG. 1B is a simplified partial cross-sectional view of the microelectronic device 100 taken through section line B-B of FIG. 1A; and FIG. 1C is a simplified partial cross-sectional view of the microelectronic device 100 taken through section line C-C of FIG. 1A.

For clarity and case of understanding the description, FIG. 1A does not illustrate some portions of the microelectronic device 100 located on an uppermost surface of the microelectronic device 100 to more clearly illustrate the relative location of portions of the microelectronic device 100 located vertically underneath (e.g., in the Z-direction) the vertically uppermost surface of the microelectronic device 100. For example, portions of a first material 106 are illustrated in FIG. 1A, even though the first material 106 is located vertically underneath (e.g., in the Z-direction) the vertically uppermost surface of the microelectronic device 100, as described and illustrated with reference to FIG. 1B and FIG. 1C. Accordingly, some of the top-down views (FIG. 1A, FIG. 1G, FIG. 1I, FIG. 1L, FIG. 1O, and FIG. 1S) of the microelectronic device 100 do not illustrate the relative vertical position (e.g., in the Z-direction) of components of the microelectronic device 100 with respect to one another; rather, the top-down views illustrated the relative horizontal positions (e.g., in the X-direction, in the Y-direction) of the illustrated components of the microelectronic device 100 with respect to one another; and the relative vertical position of the components of the microelectronic device 100 are illustrated in the cross-sectional views (FIG. 1B, FIG. 1C, FIG. 1E, FIG. 1F, FIG. 1H, FIG. 1J, FIG. 1K, FIG. 1M, FIG. 1N, FIG. 1P through FIG. 1R, FIG. 1T through FIG. 1V, and FIG. 1X) illustrated herein.

Referring to FIG. 1A, the microelectronic device 100 includes an array region 102 (also referred to herein as a “memory array region”) horizontally neighboring (e.g., in the X-direction) a staircase region 104 (also referred to herein as a “peripheral region”). In some embodiments, the staircase region 104 is horizontally interposed between (e.g., in the X-direction) array regions 102 and may be directly horizontally between (e.g., in the X-direction) the array regions 102, such as a first array region 102 and a second array region 102. In some embodiments, a horizontal area (e.g., in the XY plane) of the staircase region 104 is larger than a horizontal area of the individual array regions 102. In some embodiments, the horizontal area of the staircase region 104 is greater than the total horizontal area of the array regions 102 directly horizontally neighboring (e.g., in the X-direction) the staircase region 104.

Although FIG. 1A illustrates only one staircase region 104 and two array regions 102, the disclosure is not so limited. The microelectronic device 100 may include more than one staircase region 104 and more than two array regions 102. In some embodiments, each staircase region 104 is horizontally interposed (e.g., in the X-direction) between two array regions 102. In some embodiments, horizontally neighboring staircase regions 104 are spaced from one another (e.g., in the X-direction) by two array regions 102 (e.g., a first array region 102) in operable communication with a first staircase structure of a first staircase region 104 and a second array region 102 in operable communication with a second staircase structure of a second staircase region 104. In some embodiments, the array regions 102 may each individually horizontally neighbor (e.g., in the X-direction) a staircase region 104 and an additional array region 102. In other embodiments, the horizontal area of the staircase region 104 is less than the horizontal area of the array regions 102.

With reference to FIG. 1B and FIG. 1C, the microelectronic device 100 includes a vertical stack structure 105 (also referred to as a “stack structure”) over a base structure 110 from which a vertical stack of memory cells (e.g., vertical stack of memory cells 186 (FIG. 1W, FIG. 1X)) will be formed. The stack structure 105 includes a vertically alternating (e.g., in the Z-direction) sequence of a first material 106 and a second material 108.

The base structure 110 may include a conventional silicon substrate (e.g., a conventional silicon wafer), or another bulk substrate comprising a semiconductive material. As used herein, the term “bulk substrate” means and includes not only silicon substrates, but also silicon-on-insulator (SOI) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such monocrystalline silicon or polycrystalline silicon; silicon-germanium; germanium; gallium arsenide; a gallium nitride; and indium phosphide). In some embodiments, the base structure 110 comprises a silicon wafer.

With reference to FIG. 1A, in some embodiments, each of the array regions 102 and the staircase region 104 includes first isolation regions 103 horizontally extending (e.g., in the X-direction) through the array regions 102 and the staircase region 104. Within the array regions 102, the first isolation regions 103 may horizontally separate (e.g., in the Y-direction) horizontally neighboring (e.g., in the Y-direction) active regions (e.g., access devices 130); and within the staircase region 104, the first isolation regions 103 may horizontally separate (e.g., in the Y-direction) horizontally neighboring active regions (e.g., horizontally neighboring first materials 106). The first isolation regions 103 may vertically extend (e.g., in the Z-direction) through the stack structure 105 (FIG. 1B, FIG. 1C) and terminate at, for example, the base structure 110.

With continued reference to FIG. 1A, second isolation regions 107 may horizontally extend (e.g., in the Y-direction) through the array regions 102 and the staircase region 104. Within the array regions 102, the second isolation regions 107 may horizontally separate (e.g., in the X-direction) horizontally neighboring (e.g., in the X-direction) active regions (e.g., the access devices 130); and within the staircase region 104, the second isolation regions 107 may horizontally separate (e.g., in the Y-direction) horizontally neighboring active regions (e.g., horizontally neighboring first materials 106).

In some embodiments, horizontally neighboring (e.g., in the X-direction) access devices 130 in the array regions 102 may be separated from one another by a horizontal pitch PI (e.g., in the X-direction).

The second isolation regions 107 may individually be formed of and include a first insulative material 118. The first insulative material 118 may be formed of and include insulative material. In some embodiments, the first insulative material 118 is formed of and includes insulative material, such as one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the first insulative material 118 comprises silicon dioxide.

With reference to FIG. 1B, semiconductive material 112 vertically overlies (e.g., in the Z-direction) the stack structure 105 with the array regions 102 (FIG. 1A). In some embodiments, the semiconductive material 112 comprises silicon, such as single-crystal silicon. In some embodiments, the semiconductive material 112 comprises epitaxially-grown silicon. As described in further detail herein, the semiconductive material 112 may be used to form one or more control logic devices of the microelectronic device 100 to facilitate control operations for memory cells (e.g., memory cells 186 (FIG. 1W, FIG. 1X)) of the microelectronic device 100.

A second insulative material 114 vertically overlies (e.g., in the Z-direction) the semiconductive material 112 in the array regions 102 and the stack structure 105 within the staircase region 104. The second insulative material 114 may be formed of and include one or more of the materials described above with reference to the first insulative material 118. In some embodiments, the second insulative material 114 comprises substantially the same material composition as the first insulative material 118. For clarity and ease of understanding the description, the second insulative material 114 is not illustrated in FIG. 1A.

The first material 106 may be formed of and include, for example, a semiconductive material (e.g., silicon) or an oxide material (e.g., silicon dioxide). In some embodiments, the first material 106 comprises silicon, such as epitaxially grown silicon. In some embodiments, the first material 106 comprises monocrystalline silicon.

The second material 108 may have a different material composition than the first material 106 and may have etch selectivity with respect to the first material 106. The second material 108 may be formed of and include one or more of silicon germanium, polysilicon, a nitride material (e.g., silicon nitride (Si₃N₄)), or an oxynitride material (e.g., silicon oxynitride). In some embodiments, such as where the first material 106 comprises silicon, the second material 108 comprises silicon germanium, such as epitaxially grown silicon germanium. In other embodiments, such as where the first material 106 comprises silicon, the second material 108 comprises polysilicon. In yet other embodiments, such as where the first material 106 comprises silicon dioxide, the second material 108 comprises silicon nitride or silicon oxynitride.

With reference to FIG. 1A and FIG. 1B, a vertical stack of access devices 130 may be formed to vertically extend (e.g., in the Z-direction) through the stack structure 105. The vertical stack of access devices 130 may include vertically spaced (e.g., in the Z-direction) access devices 130, each formed within a level of the first material 106.

Within the array regions 102, the access devices 130 may comprise doped portions of the first material 106 to form channel regions 132 (FIG. 1B). The channel regions 132 may be doped with one or more of at least one N-type dopant, such as one or more of arsenic ions, phosphorous ions, and antimony ions. In other embodiments, the channel regions 132 are doped with at least one P-type dopant, such as one or more of boron ions, aluminum ions, and gallium ions. In some embodiments, the channel regions 132 of the access devices 130 are positioned horizontally between (e.g., in the X-direction, in the Y-direction) a source region and a drain region of the access devices 130. The access devices 130 vertically overlying (e.g., in the Z-direction) one another may be form a vertical stack of access devices 130.

With reference to FIG. 1A and FIG. 1C, within the staircase region 104, the first material 106 may not include access devices 130 (FIG. 1B). As described in further detail herein, within the staircase region 104, the first material 106 may be selectively removed with respect to the second material 108 and replaced with a conductive material to form portions (e.g., second conductive structures 154 (FIG. 1G, FIG. 1H)) of staircase structures (e.g., staircase structures 175 (FIG. 1W through FIG. 1X)).

In some embodiments, first conductive structures 134 vertically overlie (e.g., in the Z-direction) and vertically underlie (e.g., in the Z-direction) each of the access devices 130 within the array regions 102 and vertically overlie (e.g., in the Z-direction) and vertically underlie (e.g., in the Z-direction) each of the first materials 106 within the staircase regions 104. The first conductive structures 134 may vertically overlie and vertically underlie the channel regions 132 of each of the access devices 130. In some embodiments, the channel regions 132 are vertically surrounded by the first conductive structures 134. In some embodiments, vertically neighboring (e.g., in the Z-direction) first conductive structures 134 between vertically neighboring (e.g., in the Z-direction) access devices 130 are spaced from each other by a third insulative material 128. While the first conductive structures 134 vertically underlie (e.g., in the Z-direction) a vertically uppermost (e.g., in the Z-direction) surface of the microelectronic device 100, the first conductive structures 134 are illustrated in FIG. 1A to illustrate the relative lateral position of the first conductive structures 134 relative to other components and structures of the microelectronic device 100.

The first conductive structures 134 may individually be formed of and include conductive material, such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity.

The first conductive structures 134 may horizontally extend in a first horizontal direction (e.g., in the X-direction) as lines and may extend from one array region 102, through the staircase region 104, and to another array region 102. The first conductive structures 134 horizontally extend (e.g., in the X-direction) substantially continuously through the staircase region 104 horizontally intervening (e.g., in the X-direction) between two array regions 102. As described in further detail herein, the first conductive structures 134 may individually be referred to herein as “first conductive lines,” “access lines,” or “word lines.”

In some embodiments, the first conductive structures 134 form a vertical stack structure 135. The vertical stack structure 135 horizontally extends (e.g., in the X-direction) through at least a portion of two array regions 102 and substantially continuously through the staircase region 104 horizontally intervening (e.g., in the X-direction) between the two array regions 102. The vertical stack structure 135 comprises levels of the first conductive structures 134 vertically (e.g., in the Z-direction) spaced from one another. In some embodiments, the vertical stack structure 135 horizontally terminates (e.g., in the X-direction) within the horizontal boundaries (e.g., in the X-direction) of the array regions 102 (e.g., at the horizontal boundaries (e.g., in the X-direction) of the array regions 102). In some embodiments, the vertical stack structure 135 does not horizontally extend (e.g., in the X-direction) beyond a horizontal boundary of the array regions 102 on a horizontal side of the respective array region 102 opposite the staircase region 104.

The third insulative material 128 may be formed of and include an insulative material that is different than, and that has etch selectivity with respect to, the first material 106. In some embodiments, the third insulative material 128 is formed of and includes one or more of the materials described above with reference to the first insulative material 118. In some embodiments, the third insulative material 128 is formed of and include an oxide material (e.g., silicon dioxide).

Referring to FIG. 1B, each of the access devices 130 is at least partially surrounded by a dielectric material 136, which may also be referred to herein as a “gate dielectric material.” With reference to FIG. 1C, the first material 106 in the staircase region 104 is at least partially surrounded by the dielectric material 136. In some embodiments, the portion of the first conductive structure 134 directly vertically neighboring (e.g., in the Z-direction) and located within horizontal boundaries (e.g., in the X-direction, in the Y-direction) of the dielectric material 136 may be referred to as a “gate electrode.” In some embodiments, the first conductive structures 134 are separated from the access devices 130 by the dielectric material 136.

The dielectric material 136 may be formed of and include insulative material. By way of non-limiting example, the dielectric material 136 may comprise one or more of phosphosilicate glass, borosilicate glass, borophosphosilicate glass (BPSG), fluorosilicate glass, silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), another gate dielectric material, a dielectric carbon nitride material (e.g., silicon carbon nitride (SiCN)), or a dielectric carboxynitride material (e.g., silicon carboxynitride (SiOCN)).

Vertically neighboring (e.g., in the Z-direction) access devices 130 and levels of the first material 106 are spaced from one another by a fourth insulative material 138 (FIG. 1B, FIG. 1C). In some embodiments, the fourth insulative material 138 surrounds at least a portion of the dielectric material 136 and horizontally intervenes (e.g., in the Y-direction) between the dielectric material 136 and the second material 108.

The fourth insulative material 138 may be formed of and include insulative material having etch selectivity with respect to the second material 108. In some embodiments, the fourth insulative material 138 comprises a nitride material (e.g., silicon nitride (Si₃N₄)) or an oxynitride material (e.g., silicon oxynitride). In some embodiments, the fourth insulative material 138 comprises silicon nitride.

With reference to FIG. 1A and FIG. 1B, conductive pillar structures 140 may vertically extend (e.g., in the Z-direction) through the microelectronic device 100 and horizontally neighbor (e.g., in the Y-direction) and contact the channel regions 132 of the access devices 130. The conductive pillar structures 140 may also be referred to herein as “digit lines,” “second conductive lines,” “digit line pillar structures,” “local digit lines,” or “vertical digit lines.” Each conductive pillar structure 140 vertically extends through the microelectronic device 100, such as through or horizontally neighboring (e.g., in the Y-direction) the vertical stack of access devices 130. In some embodiments, the conductive pillar structures 140 horizontally neighbor (e.g., in the Y-direction) a source region or a drain region of the access devices 130. In other embodiments, such as where the access devices 130 consist essentially of the channel regions 132 (and do not include, for example, a source region and a drain region), the conductive pillar structures 140 directly contact the channel region 132 of the access devices 130. The conductive pillar structures 140 are individually in contact with the access devices 130 of the vertical stack of access devices 130.

The conductive pillar structures 140 may individually be formed of and include conductive material, such as one or more of the materials described above with reference to the first conductive structures 134.

With reference to FIG. 1A, in some embodiments, the staircase region 104 does not include any of the conductive pillar structures 140 within a horizontal area thereof.

With continued reference to FIG. 1B, the conductive pillar structures 140 may individually be in contact with conductive material 142 horizontally extending (e.g., in the Y-direction) from the conductive pillar structure 140 and vertically over (e.g., in the Z-direction) the second insulative material 114. For clarity and case of understanding the description, the conductive material 142 is not illustrated in FIG. 1A. The conductive material 142 may be formed of and include one or more of the materials described above with reference to the conductive pillar structures 140.

In some embodiments, the first material 106 within the array regions 102 and the staircase region 104 may be patterned (e.g., to form the access devices 130 in the array regions 102 and pattern the first material 106 in the staircase region 104) substantially concurrently. By way of non-limiting example, trenches may be formed at locations corresponding to the first isolation regions 103 (FIG. 1A through FIG. 1C). Portions of each of the levels of the second material 108 may be selectively removed through the trenches to form recesses within the second material 108 at each of the levels. Portions of the first insulative material 118 of the second isolation regions 107 may be selectively removed (e.g., in the Y-direction) with respect to the first material 106 and the second material 108 through the trenches. After removing portions of the first insulative material 118 through the trenches, portions of the second material 108 may be selectively removed in the horizontal direction (e.g., in the Y-direction) relative to the first material 106 to form recesses in the levels of the second material 108 and form levels of the first material 106 horizontally extending (e.g., in the Y-direction) closer to the trenches than levels of the second material 108.

After removing the portions of the levels of the second material 108 through the trenches, the fourth insulative material 138 may be formed over surfaces of the first material 106 and the vertically extending (e.g., in the Z-direction) surfaces of the second material 108 within the recesses. The fourth insulative material 138 may be formed as, for example, a liner material (e.g., does not substantially fill the recesses). After forming the fourth insulative material 138, the third insulative material 128 may be formed over surfaces of the fourth insulative material 138 and within remaining portions of the recesses and the trenches.

After forming the fourth insulative material 138 and the third insulative material 128, portions of the third insulative material 128 may be removed (e.g., vertical portions of the third insulative material 128 may be removed) to expose sidewalls of fourth insulative material 138. In some embodiments, the exposed portions of the fourth insulative material 138 are selectively removed (e.g., in the Y-direction) to recess the fourth insulative material 138 relative to the third insulative material 128 and expose portions of the levels of the first material 106. Exposed portions of the first material 106 may selectively be removed to vertically thin (e.g., in the Z-direction) the exposed portions of the first material 106. After vertically thinning the exposed portions of the first material 106, the dielectric material 136 is formed on surfaces of the first material 106, surfaces of the fourth insulative material 138, and surfaces of the third insulative material 128.

A conductive material may be formed over surfaces of the dielectric material 136 to form the first conductive structures 134. In some embodiments, the conductive material is formed by one or more of ALD, CVD, and PVD. After forming the conductive material, portions of the conductive material may selectively be removed (e.g., in the Y-direction) with respect to, for example, the dielectric material 136, to form the first conductive structures 134 horizontally extending (e.g., in the X-direction) as lines through the array regions 102 and the staircase regions 104, each first conductive structure 134 horizontally extending as a continuous integral structure.

After forming the first conductive structures 134, additional portions of the fourth insulative material 138 may be formed to form the access devices 130. The additional portions of the fourth insulative material 138 may be formed to horizontally neighbor (e.g., in the Y-direction) the first conductive structures 134 and may be formed on surfaces of the dielectric material 136. After forming the access devices 130, the conductive pillar structures 140 (FIG. 1A, FIG. 1B) and the conductive material 142 (FIG. 1B) may be formed within the array regions 102. The conductive pillar structures 140 (FIG. 1A, FIG. 1B) and the conductive material 142 (FIG. 1B) may not be formed within (e.g., may be omitted from) the staircase region 104. In addition, the first isolation regions 103 may be filled with the first insulative material 118.

With reference to FIG. 1A, the array regions 102 may include a central array region 119 horizontally between (e.g., in the Y-direction) edge regions 117. In some embodiments, the edge regions 117 individually include a single first conductive structure 134 horizontally extending (e.g., in the X-direction) therethrough. Each of the edge regions 117 may horizontally neighbor (e.g., in the Y-direction) a peripheral region of the microelectronic device 100, the peripheral region not including memory cells. Although FIG. 1A illustrates a particular number of sets of access devices 130 and first conductive structures 134 in the central array region 119, the disclosure is not so limited, and the microelectronic device 100 may include a greater number of access devices 130 and first conductive structures 134 in the central array region 119.

With collective reference to FIG. 1D and FIG. 1E, a first mask material 144 may be formed over the microelectronic device 100 over the array regions 102 and over portions of the staircase region 104. In some embodiments, substantially all of each of the array regions 102 is covered by the first mask material 144 and a majority of the staircase region 104 is covered by the first mask material 144. Within the staircase region 104, trenches 146 and isolation structures 148 may be formed within the first mask material. In some embodiments, the trenches 146 and the isolation structures 148 are horizontally between vertical stack structures 135 (FIG. 1A, FIG. 1E) of first conductive structures 134 (FIG. 1A, FIG. 1E) that are horizontally between (e.g., in the Y-direction) two of the first isolation regions 103. The isolation structures 148 are illustrated in dashed lines in FIG. 1D.

The isolation structures 148 may be located horizontally between (e.g., in the X-direction) the array regions 102 and the staircase regions 104. A horizontal width (e.g., in the Y-direction) of the isolation structures 148 be greater than a horizontal width (e.g., in the Y-direction) of the trenches 146. As described in further detail herein, the isolation structures 148 may form conductive routing structure regions for routing of conductive interconnections (e.g., electrical connections) of various components of the microelectronic device 100 to circuitry (e.g., sub-word line driver circuitry) of an additional microelectronic device (e.g., an additional microelectronic device structure).

With reference to FIG. 1E, the trenches 146 and the isolation structures 148 (FIG. 1D) may vertically extend (e.g., in the Z-direction) through the first mask material 144, the second insulative material 114, and the stack structure 105. In some embodiments, the trenches 146 and the isolation structures 148 vertically extend (e.g., in the Z-direction) to the base structure 110.

With continued reference to FIG. 1D and FIG. 1E, within the staircase region 104, the first isolation regions 103, the second isolation regions 107, and the trenches 146 may horizontally separate (e.g., in the Y-direction) horizontally neighboring (e.g., in the X-direction, in the Y-direction) portions of the first material 106 into isolated structures 109 (FIG. 1G), each comprising portions of the first material 106. The isolated structures 109 may be separated into rows 115 of the isolated structures 109 horizontally separated (e.g., in the Y-direction) from one another by the first isolation regions 103 and columns 113 of the isolated structures 109 horizontally separated (e.g., in the X-direction) from one another by the second isolation regions 107. In some embodiments, the microelectronic device 100 includes two rows 115 of the isolated structures 109 horizontally between (e.g., in the Y-direction) horizontally neighboring (e.g., in the Y-direction) first isolation regions 103.

The first mask material 144 may be formed of and include one or more of a photoresist material, nitride mask (e.g., silicon nitride, titanium nitride, aluminum nitride), silicon carbide, carbon doped hydrogenated silicon oxide (SiOCH), amorphous carbon, and a spin-on mask material. In some embodiments, the first mask material 144 comprises a hardmask material. However, the disclosure is not so limited and the first mask material 144 may include materials other than those described above.

With continued reference to FIG. 1E, after forming the trenches 146 and the isolation structures 148 (FIG. 1D), portions of the second material 108 (FIG. 1C) within the staircase region 104 may selectively be removed (e.g., relative to the first material 106 and the fourth insulative material 138) through the trenches 146 and the isolation structures 148. Removal of the second material 108 may expose portions of the first material 106 and portions of the fourth insulative material 138. In some embodiments, removal of the second material 108 may remove substantially all of the second material 108 from within the staircase region 104 and expose portions of the fourth insulative material 138.

In some embodiments, after removing the portions of the second material 108 (FIG. 1C), portions of the first material 106 are vertically thinned (e.g., in the Z-direction) through the trenches 146, the isolation structures 148 (FIG. 1D), and the regions from which the second material 108 was removed.

In some embodiments, the second material 108 (FIG. 1C) is removed selective to the first material 106, the second insulative material 114, the first conductive structures 134, the dielectric material 136, and the first mask material 144 by exposing the second material 108 to one or both of a dry etch process and a wet etch process. By way of non-limiting example, the second material 108 may be removed selective to the first material 106 by exposing the second material 108 to a dry etch including one or both of hydrogen fluoride (HF) and methanol (CH₃OH); followed by a plasma treatment with one or more of carbon tetrafluoride (CF₄), fluorine (F₂), ammonia (NH₃), argon, and chlorine trifluoride (ClF₃). In some embodiments, the portions of the first material 106 is vertically thinned (e.g., in the Z-direction) by exposing the first material 106 to an atomic layer etching (ALE) process.

Referring next to FIG. 1F, after selectively removing the second material 108 (FIG. 1E) relative to the first material 106 and vertically thinning (e.g., in the Z-direction) portions of the first material 106, a fifth insulative material 150 may be formed at locations corresponding to the locations of the second material 108 (FIG. 1D). The fifth insulative material 150 may be formed vertically between (e.g., in the Z-direction) vertically neighboring (e.g., in the Z-direction) levels of the first material 106.

After forming the fifth insulative material 150, portions of the fifth insulative material 150 may be removed from over surfaces of the microelectronic device 100 and from vertical sidewalls of the trenches 146 to expose sidewalls of the levels of the first material 106 at the trenches 146.

The fifth insulative material 150 may be formed of and include one or more of the materials described above with reference to the second insulative material 114. In some embodiments, the fifth insulative material 150 comprises substantially the same material composition as the second insulative material 114. In some embodiments, the fifth insulative material 150 comprises an oxide material. In some embodiments, the fifth insulative material 150 comprises silicon dioxide.

FIG. 1G and FIG. 1H are a simplified partial top-down view (FIG. 1G) and a simplified partial cross-sectional view (FIG. 1H) of the microelectronic device 100 at a processing stage subsequent to that described with reference to FIG. 1F. FIG. 1H is a simplified cross-sectional view of the microelectronic device 100 taken through section line H-H of FIG. 1G. In FIG. 1G, the first mask material 144 is not illustrated for clarity and case of understanding the description.

After forming the fifth insulative material 150, portions of the first material 106 (FIG. 1F) within the staircase region 104 may selectively be removed (e.g., relative to the fifth insulative material 150, the first conductive structures 134, and the fourth insulative material 138) through the trenches 146 and the isolation structures 148. Removal of the first material 106 may expose portions of the dielectric material 136. In some embodiments, exposed portions of the dielectric material 136 may be removed to expose portions of the first conductive structures 134. Removing the first material 106 through the trenches 146 and the isolation structures 148 may remove substantially all of the first material 106 from within the staircase region 104. In other embodiments, portions of the first material 106 may remain, such as portions of the first material 106 distal from the trenches 146 and the isolation structures 148 and proximate, for example, the first insulative material 118 of the first isolation region 103.

In some embodiments, the first material 106 is removed selective to the fifth insulative material 150, the first conductive structures 134, and the fourth insulative material 138 by exposing the first material 106 to one or both of a dry etch process (e.g., with one or more of ammonia (NH₃), sulfur hexafluoride (SF₆), hydrogen (H₂), and carbon tetrafluoride (CF₄)) or a wet etch process (e.g., with one or more of tetramethylammonium hydroxide (TMAH), deionized water (DIO₃), hydrofluoric acid (HF), ethyltrimethyl ammonium hydroxide (ETMAH) (C₅H₁₅NO), and one or more amine compounds (e.g., one or more of N-methylethanolamine (NMEA) (C₃H₉NO), monoethanolamine (MEA) (C₂₇NO), diethanolamine (DEA) (C₄H₁₁NO₂), and triethanolamine (TEA) (C₆H₁₅NO₃))). However, the disclosure is not so limited and the first material 106 may be selectively removed with materials and methods other than those described above.

After removing portions of the first material 106, the exposed portions of the dielectric material 136 may be removed selective to the fourth insulative material 138. In some embodiments, the dielectric material 136 is exposed to a wet etch process, such as to one or more of potassium hydroxide (KOH), hydrofluoric acid (HF), and ammonium fluoride (NH₄F) to selectively remove the dielectric material 136 relative to the fourth insulative material 138.

With continued reference to FIG. 1G and FIG. 1H, after removing the first material 106 (FIG. 1F) and the portions of the dielectric material 136, a conductive material 152 may be formed at locations corresponding to the first material 106 and the dielectric material 136 previously removed. In some embodiments, the conductive material 152 is formed at the levels of the stack structure 105 vertically between (e.g., in the Z-direction) vertically neighboring (e.g., in the Z-direction) levels of the fifth insulative material 150. The conductive material 152 may be in contact with the first conductive structures 134. By way of non-limiting example, each level of the conductive material 152 may be in contact with a first conductive structure 134 directly vertically above (e.g., in the Z-direction) and a first conductive structure 134 directly vertically below (e.g., in the Z-direction) the level of the conductive material 152. The conductive material 152 may horizontally extend (e.g., in the Y-direction) from the trenches 146 (FIG. 1F) to the first conductive structures 134.

In some embodiments, the conductive material 152 comprises one or more of the materials described above with reference to the first conductive structures 134. In some embodiments, the conductive material 152 comprises substantially the same material composition as the first conductive structures 134. In other embodiments, the conductive material 152 comprises a different material composition than the first conductive structures 134.

After forming the conductive material 152, portions of the conductive material 152 on vertically extending sidewalls (e.g., in the Z-direction) of the trenches 146 (FIG. 1F) and the isolation structures 148 (FIG. 1G) and vertically overlying (e.g., in the Z-direction) the microelectronic device 100 may be removed. In some embodiments, at least portions of the first mask material 144 (FIG. 1F) may be removed (e.g., thinned) from upper surfaces of the microelectronic device 100 during removal of the portions of the conductive material 152. In some embodiments, the portions of the conductive material 152 are removed by exposing the conductive material 152 to a wet etch process, such as one or more of ammonium hydroxide, hydrogen peroxide (H₂O₂), sodium hypochlorite (NaOCl), hydrogen fluoride, nitric acid (HNO₃), and sulfuric acid (H₂SO₄).

With collective reference to FIG. 1G and FIG. 1H, horizontally extending (e.g., in the Y-direction) portions of the conductive material 152 remain at the levels of the stack structure 105 after removal of the conductive material 152 from vertically extending sidewalls (e.g., in the Z-direction) defining the trenches 146 (FIG. 1F). The horizontally extending portions of the conductive material 152 may form second conductive structures 154 horizontally extending (e.g., in the Y-direction) at least from the first conductive structures 134 and horizontally terminating at, for example, the trenches 146. Thus, the second conductive structures 154 may individually be in contact with the first conductive structures 134. In some embodiments, the second conductive structures 154 horizontally extend in a horizontal direction (e.g., in the Y-direction) substantially perpendicular to a horizontal direction (e.g., the X-direction) in which the first conductive structures 134 horizontally extend. Thus, the vertical stack structures 135 may include the first conductive structures 134 (e.g., substantially linear first conductive structures 134) horizontally extending in a first horizontal direction (e.g., in the X-direction) from the array regions 102 (e.g., through vertical stacks of memory cells (e.g., memory cells 186 (FIG. 1W, FIG. 1X))) and through the staircase region 104; and the second conductive structures 154 horizontally extending in a second horizontal direction (e.g., in the Y-direction) from the first conductive structures 134.

With reference to FIG. 1G, the previously illustrated isolated structures 109 (FIG. 1A) of the first material 106 (FIG. 1A) within the staircase region 104 are illustrated with the conductive material 152 which may vertically intervene (e.g., in the Z-direction) between levels of the fifth insulative material 150.

In some embodiments, the second conductive structures 154 intersect the first conductive structures 134 and horizontally extend (e.g., in the Y-direction) beyond lateral boundaries (e.g., in the Y-direction) of the first conductive structures 134. With reference to FIG. 1G, the second conductive structures 154 may be located on both horizontal sides (e.g., in the Y-direction) of the first conductive structures 134 of the vertical stack structure 135. In some embodiments, the first conductive structures 134 may be located within horizontal boundaries (e.g., in the Y-direction) of the second conductive structures 154.

With continued reference to FIG. 1G and FIG. 1K, after removing the conductive material 152 from surfaces of the microelectronic device 100 and sidewalls of the trenches 146 (FIG. 1A, FIG. 1F) and the isolation structures 148, the trenches 146 and isolation structures 148 may be filled with additional portions of the first insulative material 118. Portions of the first insulative material 118 may be removed, such as by exposing the microelectronic device 100 to a chemical-mechanical planarization (CMP) process.

FIG. 1I through FIG. 1K are a simplified partial top-down view (FIG. 1I) and simplified partial cross-sectional views (FIG. 1J, FIG. 1K) of the microelectronic device 100 at a processing stage subsequent to that described with reference to FIG. 1G and FIG. 1H. FIG. 1J is a simplified cross-sectional view of the microelectronic device 100 taken through section line J-J of FIG. 1I. FIG. 1K is a simplified cross-sectional view of the microelectronic device 100 taken through section line K-K of FIG. 1I. For clarity and understanding of the description, FIG. 1J and FIG. 1K illustrate more levels of the conductive material 152 and the fifth insulative material 150 than FIG. 1H to more clearly illustrate the formation of first steps (e.g., first steps 155 (FIG. 1J, FIG. 1K)) of a staircase structure (e.g., structures 175 (FIG. 1W through FIG. 1X)). It will be understood that FIG. 1J and FIG. 1K are not illustrated to scale with respect to FIG. 1H.

With collective reference to FIG. 1J and FIG. 1K, the array regions 102 and portions of the staircase region 104 may be covered with one or more mask materials, such as a first buried anti-reflective coating (BARC) material 156 and a first resist material 158. For clarity and case of understanding the description, the first BARC material 156 and the first resist material 158 are not illustrated in FIG. 1I. FIG. 1J and FIG. 1K do not illustrate the base structure 110. It will be understood that the microelectronic device 100 includes multiple levels of the second conductive structures 154 and the fifth insulative material 150.

Openings 160 may be formed in the first BARC material 156 and the first resist material 158 to expose a vertically uppermost (e.g., in the Z-direction) tier of the levels of the conductive material 152 and the fifth insulative material 150 of portions of the isolated structures 109. In some embodiments, the openings 160 in the edge regions 117 may be horizontally (e.g., in the X-direction) offset (e.g., staggered) from the openings 160 in the central array region 119.

The first BARC material 156 may be formed of and include one or more of titanium, titanium dioxide, chromium oxide, magnesium fluoride (MgF₂), carbon, alpha-silicon, or an organic material (e.g., a fluorine-containing polymer), a dielectric anti-reflective coating (DARC) material. However, the disclosure is not so limited and the first BARC material 156 may include materials other than those described above.

The first resist material 158 may be formed of and include a methacrylate copolymer with siloxane groups, methyl methacrylate, diazonaphthoquinone (DNQ), a copolymer of tert-butyl methacrylate and 3-heptaisobutyl-POSS-propyl methacrylate, and a negative photoresist (e.g., hydrogen silsesquioxane (HSQ)). However, the disclosure is not so limited and the first resist material 158 may include materials other than those described above.

Referring to FIG. 1J and FIG. 1K, after exposing the additional portions of the isolated structures 109, portions of additional levels of the fifth insulative material 150 and the conductive material 152 of the second conductive structures 154 may be removed through the openings 160. By way of non-limiting example, portions of the vertically uppermost (e.g., in the Z-direction) at least three levels (e.g., four levels) of each of the fifth insulative material 150 and the second conductive structures 154 may be removed through the openings 160 to expose the vertically underlying (e.g., in the Z-direction) second conductive structure 154 to form first steps 155, each of the first steps 155 horizontally neighboring at least another of the first step 155 in a first horizontal direction (e.g., in the X-direction) and vertically spaced from the at least another first step 155 by at least three levels (e.g., at least three pairs) of the fifth insulative material 150 and the second conductive structures 154, such as four levels of the fifth insulative material and the second conductive structures 154.

In some embodiments, the levels of the fifth insulative material 150 and the conductive material 152 of the second conductive structures 154 may be removed by dry etching, such as by reactive ion etching (RIE). By way of non-limiting example, the fifth insulative material 150 may be removed by exposing the fifth insulative material 150 to one or more of hydrogen (H₂), carbon tetrafluoride (CF₄), fluoromethane (CH₃F), hexafluoroethane (C₂F₆), octafluoropropane (C₃F₈), and octafluorocyclopentene (C₅F₈). The portions of the levels of the second conductive structures 154 may be removed by exposing the second conductive structure 154 to one or more of sulfur hexafluoride (SF₆), oxygen (O₂), ammonia (NH₃), carbon tetrafluoride, fluoromethane, and bromotrifluoromethane (CBrF₃). However, the disclosure is not so limited and the portions of each of the fifth insulative material 150 and the second conductive structures 154 may be removed by methods other than those described above.

FIG. 1L through FIG. 1N are a simplified partial top-down view (FIG. 1L) and simplified partial cross-sectional views (FIG. 1M, FIG. 1N) of the microelectronic device 100 at a processing stage subsequent to that described with reference to FIG. 1I and FIG. 1K. FIG. 1M is a simplified cross-sectional view of the microelectronic device 100 taken through section line M-M of FIG. 1L. FIG. 1N is a simplified cross-sectional view of the microelectronic device 100 taken through section line N-N of FIG. 1L.

With collective reference to FIG. 1L through FIG. 1N, portions of the first BARC material 156 and the first resist material 158 in the staircase region 104 may be trimmed (e.g., removed) in a horizontal direction (e.g., in the X-direction) to expose additional portions of the isolated structures 109, such as one or two additional columns 113 of the isolated structures 109, through the openings 160.

With reference to FIG. 1M and FIG. 1N, after exposing the additional portions of the isolated structures 109, additional portions of additional levels of the fifth insulative material 150 and the conductive material 152 (e.g., at least three additional levels, such as four additional levels of each of the fifth insulative material 150 and the conductive material 152) may be removed to form additional first steps 155 vertically ascending and descending (e.g., in the Z-direction) in the first horizontal direction (e.g., in the X-direction). After forming the additional first steps 155, additional portions of the first BARC material 156 and the first resist material 158 in the staircase region 104 may be removed (e.g., trimmed) in the first horizontal direction to expose additional portions of the isolated structures 109, such as one or two additional columns 113 of the isolated structures 109, through the openings 160. After exposing the additional portions of the isolated structures 109, further additional first steps 155 may be formed by removing additional portions of additional levels of the fifth insulative material 150 and the conductive material 152 of the second conductive structures 154 exposed through the openings 160. The process of trimming the first BARC material 156 and the first resist material 158 to horizontally extend the openings 160 in the first horizontal direction (e.g., in the X-direction) and expose additional portions of the levels of the fifth insulative material 150 and the conductive material 152, followed by removing exposed portions of additional levels of the fifth insulative material 150 and the conductive material 152 may be repeated a desired number of times to form partial staircase structures 165 comprising the a desired number of first steps 155.

In some embodiments, each of the first steps 155 is vertically spaced (e.g., in the Z-direction) from a directly horizontally neighboring (e.g., in the X-direction) first step 155 by at least three levels of the pairs of the fifth insulative material 150 and the conductive material 152. In some embodiments, each of the first steps 155 is vertically spaced from a directly horizontally neighboring (e.g., in the X-direction) first step 155 by at least four levels of the pairs of the fifth insulative material 150 and the conductive material 152.

With continued reference to FIG. 1M, in some embodiments, after forming the first steps 155, a mask material (e.g., a chop mask) may be formed over a first region 151 of the microelectronic device 100 and a second region 153 (FIG. 1L, FIG. 1M) of the staircase region 104 may be exposed through the mask material. In some embodiments, levels of the fifth insulative material 150 and the conductive material 152 of the exposed portions of the isolated structures 109 in the second region 153 may be removed to form first steps 155 in the second region 153 that are vertically offset (e.g., in the Z-direction) from first steps 155 in the first region 151.

With reference to FIG. 1N, in some embodiments, within the edge regions 117, the partial staircase structures 165 comprising the first steps 155 form stadium structures 167 each comprising two partial staircase structures 165, a vertically lowermost (e.g., in the Z-direction) first step 155 of the stadium structures 167 horizontally centered (e.g., in the X-direction) within the stadium structure 167. In some embodiments, a first partial staircase structure 165 of a stadium structure 167 comprises first steps 155 vertically ascending (e.g., in the Z-direction) in a positive horizontal direction (e.g., in the positive X-direction) and a second partial staircase structure 165 of the stadium structure 167 comprises first steps 155 vertically ascending (e.g., in the Z-direction) in a negative horizontal direction (e.g., in the negative X-direction) substantially opposite the positive horizontal direction. It will be understood that the stadium structure 167 may include additional first steps 155 (e.g., to the left and right in the view of FIG. 1N) than those illustrated in FIG. 1N.

FIG. 1O and FIG. 1P are a simplified partial top-down view (FIG. 1O) and a simplified partial cross-sectional view (FIG. 1P) of the microelectronic device 100 at a processing stage subsequent to that described with reference to FIG. 1L through FIG. 1N. FIG. 1P is a simplified cross-sectional view of the microelectronic device 100 taken through section line P-P of FIG. 1O.

With collective reference to FIG. 1O and FIG. 1P, after forming the partial staircase structures 165 including the first steps 155 extending in the first horizontal direction (e.g., the X-direction), the first BARC material 156 and the first resist material 158 may be trimmed in a second horizontal direction (e.g., in the Y-direction) to increase a horizontal dimension of the openings 160 in the second horizontal direction and expose additional portions of the levels of the fifth insulative material 150 and the conductive material 152 of the isolated structures 109. In some embodiments, after exposing the additional portions of the levels of the fifth insulative material 150 and the conductive material 152 portions of one pair of the levels of the fifth insulative material 150 and the conductive material 152 are removed to form second steps 162 within each of the first steps 155 (FIG. 1M, FIG. 1N) of the partial staircase structure 165 and form a staircase structure 175 (FIG. 1S) comprising the first steps 155 vertically ascending and descending (e.g., in the Z-direction) in the first horizontal direction (e.g., in the X-direction) and second steps 162 vertically ascending and descending (e.g., in the Z-direction) in the second horizontal direction (e.g., in the Y-direction).

The process of trimming the first BARC material 156 and the first resist material 158 in the second horizontal direction to increase the horizontal dimension of the openings 160 in the second horizontal dimension and expose additional portions of the levels of the fifth insulative material 150 and the conductive material 152, followed by removing additional exposed portions of the levels of the fifth insulative material 150 and the conductive material 152 may be repeated a desired number of times to form staircase structures 175 (FIG. 1S, four of which are illustrated in FIG. 1S), each individually comprising sub-staircase structures 170 facing one another and individually including second steps 162 extending in the second horizontal direction (e.g., in the Y-direction) substantially perpendicular to the first horizontal direction (e.g., the X-direction). In some embodiments, the second steps 162 vertically ascend and descend (e.g., in the Z-direction) in a second horizontal direction (e.g., in the Y-direction) substantially perpendicular to a first horizontal direction (e.g., in the X-direction) in which the first steps 155 vertically ascend and descend (e.g., in the Z-direction).

In some embodiments, each sub-staircase structure 170 is formed from one of the first steps 155 (FIG. 1M) and individually comprises at least three (e.g., four) second steps 162 vertically ascending and descending (e.g., in the Z-direction) in the second horizontal direction (e.g., in the Y-direction). Horizontally neighboring (e.g., in the X-direction) sub-staircase structures 170 sharing the same first conductive structures 134 may be vertically offset (e.g., in the Z-direction) from one another by at least three (e.g., four) pairs of levels of the fifth insulative material 150 and the second conductive structures 154. In some embodiments, within the central array region 119, sub-staircase structures 170 of a staircase structure 175 may be vertically aligned (e.g., in the Z-direction) with sub-staircase structures 170 of a horizontally neighboring (e.g., in the Y-direction) that located within horizontal boundaries (e.g., in the X-direction) thereof. In some embodiments, at least some of the (e.g., each of the) sub-staircase structures 170 within the edge regions 117 may be vertically offset (e.g., in the Z-direction) from sub-staircase structure 170 that are located within horizontal boundaries (e.g., in the X-direction) of the at least some of the sub-staircase structures 170 of a horizontally neighboring (e.g., in the Y-direction) staircase structure 175.

Accordingly, each of the staircase structure 175 may include a first portion of the vertical stack structure 135 comprising the first conductive structures 134 horizontally extending in the first horizontal direction from the array regions 102 and proximate (e.g., through) the vertical stacks of access devices 130 and second conductive structures 154 horizontally extending from the first conductive structures 134 in the second horizontally direction. In some embodiments, each of the first conductive structures 134 is configured to be in electrical communication with memory cells (e.g., structures 175 (FIG. 1W through FIG. 1X)) by means of respective access devices 130 of a first array region 102 and a second array region 102 spaced from the first array region 102 by the staircase region 104.

With continued reference to FIG. 1P, pairs of the sub-staircase structures 170 horizontally aligned (e.g., in the X-direction) with one another and located on vertically aligned (e.g., in the Z-direction) first steps 155 (FIG. 1M, FIG. 1N) of horizontally neighboring (e.g., in the Y-direction) staircase structures 175 may form an additional stadium structure 172 including the pair of sub-staircase structures 170 facing one another. Each of the sub-staircase structures 170 may include first conductive structures 134 of different vertical stack structure 135. In some such embodiments, the additional stadium structures 172 may be formed from sub-staircase structures 170 associated with different first conductive structures 134 and second conductive structures 154.

In some embodiments, horizontally neighboring (e.g., in the X-direction) sub-staircase structures 170 are separated from one another by one of the second isolation regions 107 comprising the first insulative material 118.

FIG. 1Q is a simplified partial cross-sectional view of the microelectronic device 100 at a processing stage subsequent to that described with reference to FIG. 1P. After forming the sub-staircase structures 170, in some embodiments, a conductive material 173 is formed vertically over (e.g., in the Z-direction) the first steps 155 (FIG. 1N) and the second steps 162 of the staircase structures 175. Vertically extending portions (e.g., in the Z-direction) of the conductive material 173 may be removed, such as portions of the conductive material 173 vertically extending between horizontally neighboring (e.g., in the X-direction) sub-staircase structures 170 and vertically neighboring (e.g., in the Z-direction) second steps 162 of the sub-staircase structures 170. As described in further detail herein, the conductive material 173 may merge two horizontally neighboring (e.g., in the X-direction) isolated structures 109 (FIG. 1O) to form horizontally wider (e.g., in the X-direction) surfaces for forming conductive contact structures (e.g., conductive contact structures 180 (FIG. 1S through FIG. 1U)) on each of the second steps 162. In some embodiments, the conductive material 173 individually overlying each of the second steps 162 constitutes a portion of the respective second step 162. In other words, the second steps 162 may comprise the conductive material 173. In some embodiments, the conductive material 173 is not formed vertically over the sub-staircase structures 170.

The conductive material 173 may be formed of and include one or more of the materials described above with reference to the conductive material 152. In some embodiments, the conductive material 173 comprises substantially the same material composition as the conductive material 152. In some embodiments, the conductive material 173 comprises tungsten.

With continued reference to FIG. 1Q, after forming the conductive material 173, a liner material 174 may be formed vertically over (e.g., in the Z-direction) the microelectronic device 100, such as over the second steps 162 of the sub-staircase structures 170. After forming the liner material 174, a sixth insulative material 176 may be formed over the microelectronic device 100, such as over the sub-staircase structures 170 and within the additional stadium structures 172 over the liner material 174. After forming the liner material 174 and the sixth insulative material 176, horizontally extending (e.g., in the X-direction, in the Y-direction) portions of the liner material 174 and the sixth insulative material 176 may be removed from upper surfaces (e.g., in the Z-direction) of the microelectronic device 100, such as by CMP.

The liner material 174 may be formed of and include a dielectric material, such as one or more of aluminum oxide (e.g., Al₂O₃), silicon oxynitride (SiON), magnesium oxide, cerium oxide. However, the disclosure is not so limited, and the liner material 174 may be formed of and include other materials.

The sixth insulative material 176 may exhibit an etch selectivity with respect to the liner material 174. The sixth insulative material 176 may be formed of and include insulative material, such as one or more of the materials described above with reference to the first insulative material 118. In some embodiments, the sixth insulative material 176 comprises silicon dioxide.

In some embodiments, horizontally extending (e.g., in the X-direction, in the Y-direction) of the liner material 174 and the sixth insulative material 176 are removed from uppermost surfaces (e.g., in the Z-direction) of the microelectronic device 100, such as by CMP.

With continued reference to FIG. 1Q, after forming the liner material 174 and the sixth insulative material 176, openings 178 may be formed in the sixth insulative material 176 horizontally aligned (e.g., in the X-direction, in the Y-direction) with the second steps 162 and vertically over (e.g., in the Z-direction) the second steps 162 to expose portions of the liner material 174 vertically overlying (e.g., in the Z-direction) the second steps 162. In some embodiments, the openings 178 are horizontally aligned (e.g., in the X-direction, in the Y-direction) with the horizontal edges of the second steps 162.

FIG. 1R is a simplified partial cross-sectional view of the microelectronic device 100 at a processing stage subsequent to that described with reference to FIG. 1Q. After forming the openings 178, portions of the liner material 174 exposed through the openings 178 may be removed to expose horizontally extending surfaces (e.g., in the X-direction, in the Y-direction) and vertically extending surfaces (e.g., in the Z-direction) of the second steps 162 of the sub-staircase structures 170 (e.g., horizontally extending surfaces and vertically extending surfaces of the conductive material 173 and/or the conductive material 152), such horizontally extending surfaces and vertically extending surfaces substantially perpendicular to one another. In some embodiments, removing the liner material 174 may expose one or both of the conductive material 173 and the conductive material 152 at the horizontal edges (e.g., in the Y-direction) of the second steps 162 defining the sub-staircase structures 170.

In some embodiments, the exposed portions of the second steps 162 of the sub-staircase structures 170 may exhibit an “L-shape” when viewed in the cross-section illustrated in FIG. 1R. The exposed portions of the of the second steps 162 may include, for example, horizontally extending surfaces and vertically extending surfaces substantially perpendicular to the horizontally extending surfaces.

The portions of the liner material 174 may be removed by exposing the liner material 174 to, for example, a dry etch process, such as a reactive ion etching (RIE) process. In some embodiments, the exposed portions of the liner material 174 are exposed to a plasma, such as one or more of boron trichloride (BCl₃), chlorine (Cl₂), carbon tetrachloride (CCl₄), silicon tetrachloride (SiCl₄), ammonia (NH₃), and oxygen (O₂). However, the disclosure is not so limited, and the exposed portions of the liner material 174 may be removed with other etchants.

FIG. 1S through FIG. 1V are a simplified partial top-down view (FIG. 1S), and simplified partial cross-sectional views (FIG. 1T through FIG. 1V) of the microelectronic device 100 at a processing stage subsequent to that described with reference to FIG. 1R. FIG. 1T is a simplified partial cross-sectional view of the microelectronic device 100 of FIG. 1S taken through section line T-T of FIG. 1S. FIG. 1U is a simplified partial cross-sectional view of the microelectronic device 100 of FIG. 1S taken through section line U-U of FIG. 1S. FIG. 1V is a simplified partial cross-sectional view of the microelectronic device 100 of FIG. 1S taken through section line V-V of FIG. 1S.

Referring to FIG. 1S, the sub-staircase structures 170 may be horizontally spaced (e.g., in the X-direction) at a pitch P₂ that is about two times the pitch PI (FIG. 1A) of the horizontal spacing (e.g., in the X-direction) of the access devices 130 in the array regions 102 (and the corresponding pitch P₁ of memory cells) (e.g., structures 175 (FIG. 1W through FIG. 1X)) formed from the access devices 130.

With reference to FIG. 1S through FIG. 1V, after removing the exposed portions of the liner material 174 through the openings 178 (FIG. 1R), conductive contact structures 180 may be formed within the openings 178 and in contact with the second conductive structures 154 defining the second steps 162 of the sub-staircase structures 170, such as one or both of the conductive material 173 and the conductive material 152 of the second steps 162. The conductive contact structures 180 may individually contact horizontally extending (e.g., in the X-direction, in the Y-direction) surfaces of the second steps 162 of the sub-staircase structures 170, such as of the conductive material 173 or the conductive material 152; and the conductive contact structures 180 may individually contact vertically extending (e.g., in the Z-direction) surfaces of the second steps 162 of the sub-staircase structures 170, such as vertically extending surfaces of the conductive material 173 and the conductive material 152.

In some embodiments, each of the second steps 162 individually directly contacts one of the conductive contact structures 180 and each of the sub-staircase structures 170 is contacted by at least three of (e.g., four of) the conductive contact structures 180 (e.g., different levels of the second conductive structures 154 defining horizontal edges (e.g., in the X-direction) of the second steps 162 of the sub-staircase structures 170 are in contact with a different conductive contact structure 180). In some embodiments, each of the sub-staircase structures 170 comprises four levels of exposed portions of the second conductive structures 154. In some such embodiments, each of the sub-staircase structures 170 is directly contacted by four of the conductive contact structures 180 (e.g., one conductive contact structure 180 at each of the second step 162 of the sub-staircase structures 170).

With reference to FIG. 1S and FIG. 1V, in some embodiments, forming the conductive material 173 may merge pairs of horizontally neighboring (e.g., in the X-direction) to form the sub-staircase structures 170 and having the pitch P₂ of about two times the pitch P₁.

In some embodiments, within the edge regions 117, the sub-staircase structures 170 may be arranged to form stadium structures 167, a vertically lowermost (e.g., in the Z-direction) first step 155 (corresponding to a vertically lowermost sub-staircase structure 170) located substantially horizontally centrally (e.g., in the X-direction) between a first array region 102 and a second array region 102 spaced from the first array region 102 by the staircase region 104. In some such embodiments, vertically uppermost (e.g., in the Z-direction) sub-staircase structures 170 may be located proximate (e.g., directly horizontally neighboring (e.g., in the X-direction)) the array regions 102. In some embodiments, a vertical height (e.g., in the Z-direction) of the sub-staircase structures 170 within the edge regions 117 decreases with an increasing horizontal distance (e.g., in the X-direction) of the sub-staircase structures 170 from the array regions 102.

With collective reference to FIG. 1S through FIG. 1V, in some embodiments, the sub-staircase structures 170 of a first staircase structure 175 within the central array region 119 are vertically aligned (e.g., in the Z-direction) with sub-staircase structures 170 of a horizontally neighboring (e.g., in the Y-direction) second staircase structure 175 located within horizontal boundaries (e.g., in the X-direction) of the sub-staircase structures 170 of the first staircase structure 175. By way of non-limiting example, a first sub-staircase structure 170 of the first staircase structure 175 may be located within horizontal boundaries (e.g., in the X-direction) of a second sub-staircase structure 170 of the second staircase structure 175 and may be vertically aligned (e.g., in the Z-direction) with the second sub-staircase structure 170.

In some embodiments, the sub-staircase structures 170 of the first staircase structure 175 within the central array region 119 may be vertically offset (e.g., in the Z-direction) with sub-staircase structures 170 of a horizontally neighboring (e.g., in the Y-direction) third staircase structure 175 located within the edge region 117 and that are located within horizontal boundaries (e.g., in the X-direction) of the sub-staircase structures 170 of the first staircase structure 175. By way of non-limiting example, a first sub-staircase structure 170 of the first staircase structure 175 (within the central array region 119) may be located within horizontal boundaries (e.g., in the X-direction) of a third sub-staircase structure 170 of the third staircase structure 175 (within the edge region 117) and may be vertically offset (e.g., in the Z-direction) with the third sub-staircase structure 170.

The conductive contact structures 180 may be formed of and include conductive material, such as one or more of the materials described above with reference to the first conductive structures 134. In some embodiments, the conductive contact structures 180 individually comprise substantially the same material composition as the first conductive structures 134. In some embodiments, the conductive contact structures 180 individually comprise tungsten.

Although FIG. 1W through FIG. 1X illustrate that the staircase structures 175 individually include a particular number of second steps 162 (e.g., thirty-two second steps 162; eight (8) sub-staircase structures 170, each including four (4) second step 162), the disclosure is not so limited. In other embodiments, the staircase structures 175 may individually include a desired quantity of the sub-staircase structures 170 and a desired quantity of total second steps 162 (e.g., a desired quantity of levels of second conductive structures 154). In some embodiments, the staircase structures 175 individually include a quantity of second steps 162 within a range of from about thirty-two (32) of the second steps 162 to two hundred fifty-six (256) of the second steps 162. In some embodiments, the staircase structures 175 each individually include sixty-four (64) of the second steps 162. In other embodiments, the staircase structures 175 each individually include ninety-six (96) or more of the second steps 162. In other embodiments, the staircase structures 175 each individually include a different number of the second steps 162, such as less than sixty-four (64) of the second steps 162 (e.g., less than or equal to sixty (60) of the second steps 162, less than or equal to fifty (50) of the second steps 162, less than about forty (40) of the second steps 162, less than or equal to thirty (30) of the second steps 162, less than or equal to twenty (20) of the second steps 162, less than or equal to ten (10) of the second steps 162); or greater than sixty-four (64) of the second steps 162 (e.g., greater than or equal to seventy (70) of the second steps 162, greater than or equal to one hundred (100) of the second steps 162, greater than or equal to about one hundred twenty-eight (128) of the second steps 162, greater than two hundred fifty-six (256) of the second steps 162).

FIG. 1W and FIG. 1X are a simplified partial top-down view (FIG. 1W) and a simplified partial cross-sectional view (FIG. 1X) of the microelectronic device 100 at a processing stage subsequent to that described with reference to FIG. 1S through FIG. 1V. FIG. 1X is a simplified partial cross-sectional view of the microelectronic device 100 of FIG. 1W taken through section line X-X of FIG. 1W.

Storage devices 185 (e.g., capacitors) may be formed within the array regions 102, each storage device 185 individually in contact with the access devices 130. The storage devices 185 may form a vertical stack of storage devices 185 comprising vertical levels of storage devices 185 individually in contact with a level of an access device 130 of the vertical stack of access devices 130. Each access device 130 in contact with a storage device 185 may form a memory cell 186 and the vertical stack of access devices 130 coupled to the vertical stack of storage devices 185 may be form a corresponding vertical stack of memory cells 186. Accordingly, the vertical stack of memory cells 186 may individually include be vertically spaced (e.g., in the Z-direction) levels of memory cells 186, each memory cell 186 individually comprising a storage device 185 horizontally neighboring (e.g., in the Y-direction) an access device 130.

Although FIG. 1W illustrates that each of the array regions 102 individually comprises sixteen (16) vertical stacks of memory cells 186 (e.g., four (4) rows and four (4) columns of the vertical stacks of memory cells 186), the disclosure is not so limited, and the array regions 102 may individually include greater than sixteen vertical stacks of memory cells 186.

With continued reference to FIG. 1W and FIG. 1X, in some embodiments, the storage devices 185 are in contact with a conductive plate structure 187. By way of non-limiting example, a second electrode 184 of the storage devices 185 are in contact with the conductive plate structure 187. The conductive plate structure 187 may be formed of and include conductive material, such as one or more of the materials of an electrode (e.g., a second electrode 184) of the storage devices 185. In some embodiments, the conductive plate structure 187 comprises substantially the same material composition as an electrode of the storage devices 185. In other embodiments, the conductive plate structure 187 comprises a different material composition than the electrodes of the storage devices 185. The conductive plate structures 187 may be referred to herein as “conductive plates” or “ground structures.” The conductive plate structures 187 horizontally extend (e.g., in the X-direction) as conductive plates. In some embodiments, and with reference to FIG. 1W, the conductive plate structures 187 horizontally extend in substantially the same direction and are substantially parallel to the first conductive structures 134 of the vertical stack structure 135. The conductive plate structures 187 may be horizontally between (e.g., in the Y-direction) vertical stacks of memory cells 186, such as between vertical stacks of storage devices 185.

Each of the storage devices 185 individually comprises a first electrode 182 (also referred to herein as an “outer electrode,” “a first electrode plate,” or a “first node structure”), a second electrode 184 (also referred to herein as an “inner electrode,” “a second electrode plate,” or a “second node structure”), and a dielectric material 183 between the first electrode 182 and the second electrode 184. In some such embodiments, the storage devices 185 individually comprise capacitors. However, the disclosure is not so limited and in other embodiments, the storage devices 185 may each individually comprise other structures, such as, for example, phase change memory (PCM), resistance random-access memory (RRAM), conductive-bridging random-access memory (conductive bridging RAM), or another structure for storing a logic state.

At least a portion of each storage device 185 is in contact with a horizontally neighboring (e.g., in the X-direction) access device 130. In some embodiments, the first electrode 182 of each storage device 185 contacts a horizontally neighboring access device 130.

The first electrode 182 may be formed of and include conductive material such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium), polysilicon, and other materials exhibiting electrical conductivity. In some embodiments, the first electrode 182 comprises titanium nitride.

The second electrode 184 may be formed of and include conductive material. In some embodiments, the second electrode 184 comprises one or more of the materials described above with reference to the first electrode 182. In some embodiments, the second electrode 184 comprises substantially the same material composition as the first electrode 182.

The dielectric material 183 may be formed of and include one or more of silicon dioxide (SiO₂), silicon nitride (Si₃N₄), polyimide, titanium dioxide (TiO₂), tantalum oxide (Ta₂O₅), aluminum oxide (Al₂O₃), an oxide-nitride-oxide material (e.g., silicon dioxide-silicon nitride-silicon dioxide), strontium titanate (SrTiO₃) (STO), barium titanate (BaTiO₃), hafnium oxide (HfO₂), zirconium oxide (ZrO₂), a ferroelectric material (e.g., ferroelectric hafnium oxide, ferroelectric zirconium oxide, lead zirconate titanate (PZT)), and a high-k dielectric material.

The second electrode 184 may be in contact with one of the conductive plate structures 187 of a vertical stack of memory cells 186. In some embodiments, the second electrodes 184 are substantially integral with the conductive plate structures 187. With reference to FIG. 1X, in some embodiments, the second electrodes 184 of horizontally neighboring (e.g., in the X-direction) vertical stacks of storage devices 185 contact the same conductive plate structure 187. In some embodiments, the conductive plate structures 187 are individually formed of conductive material, such as one or more of the materials of the second electrode 184. In some embodiments, the conductive plate structures 187 comprise substantially the same material composition as the second electrode 184. In other embodiments, the conductive plate structures 187 comprise a different material composition than the second electrode 184.

With reference to FIG. 1X, the staircase region 104 is horizontally between (e.g., in the X-direction) horizontally neighboring array regions 102 including the vertical stacks of memory cells 186. Staircase structures 175 are located horizontally between (e.g., in the X-direction) the array regions 102. The staircase structures 175 individually include a vertical stack structure 135 of the first conductive structures 134 that horizontally extend (e.g., in the X-direction) through the staircase region 104 and into each of the array regions 102.

In use and operation, the first conductive structures 134 may individually be configured to provide sufficient voltage to the channel region 132 directly vertically neighboring (e.g., in the Z-direction) the respective access device 130 to electrically couple a storage device 185 horizontally neighboring (e.g., in the Y-direction) and associated with the access device 130 to, for example, a conductive pillar structure 140 vertically extending proximate the vertical stack of access devices 130 of the vertical stack of memory cells 186. Stated another way, each of the first conductive structures 134 may individually comprise a gate structure configured to provide a sufficient voltage to the channel region 132 vertically neighboring (e.g., in the Z-direction) the first conductive structure 134 to electrically couple the access device 130 including the channel region 132 to the horizontally neighboring (e.g., in the Y-direction) storage device 185. Since the first conductive structures 134 are configured to provide a voltage to the memory cells 186 (e.g., by means of a voltage applied to the corresponding second conductive structures 154 by means of the respective conductive contact structure 180), the first conductive structures 134 may individually be referred to herein as “first conductive lines,” “access lines,” or “word lines.”

Accordingly, the first conductive structures 134 may be driven (e.g., a voltage may be applied to the first conductive structures 134) of the memory cells 186 of two different array regions 102 by applying a voltage to one or more of the conductive contact structures 180 located in the staircase structure 175 in the staircase region 104. In some embodiments, each individual first conductive structure 134 is configured to provide a voltage (e.g., a drive voltage, an access voltage) to levels of memory cells 186 in each of two array regions 102, the array regions 102 horizontally separated from one another by the staircase region 104.

Still referring to FIG. 1W and FIG. 1X, global digit lines 188 may be formed over the vertical stacks of memory cells 186. Each global digit line 188 may be configured to be in electrical communication with more than one of the conductive pillar structures 140 by means of, for example, a transistor (e.g., a multiplexer) of the semiconductive material 112. The transistor of the semiconductive material 112 may be in contact with conductive interconnect structures 189 that are in contact with the global digit line 188 and the conductive pillar structures 140. Routing structures 190 provide a conductive path from one of the conductive interconnect structures 189 in contact with the transistor of the semiconductive material 112 and a conductive interconnect structure 189 in contact with the conductive pillar structure 140.

Each of the global digit lines 188 may be in contact with more than one vertical stacks of memory cells 186 (e.g., more than one conductive pillar structure (local digit line) 140 of different vertical stacks of memory cells 186).

The global digit lines 188 may also be referred to as “conductive lines.” The global digit lines 188 may be formed vertically over (e.g., in the Z-direction) and in electrical communication with the conductive pillar structures 140 by means of transistors within the semiconductive material 112. With reference to FIG. 1W, the global digit lines 188 are located within the array regions 102 and extend in a horizontal direction (e.g., the Y-direction) substantially perpendicular to the vertical stack structures 135.

With continued reference to FIG. 1X, in some embodiments, the conductive plate structure 187 is in configured to be in electrical communication with transistors of the semiconductive material 112 by means of additional ones of the conductive interconnect structures 189 and the routing structures 190.

Each of the conductive interconnect structures 189 and the routing structures 190 individually comprises conductive material, such as one or more of the materials described above with reference to the first conductive structures 134. In some embodiments, each of the conductive interconnect structures 189 and the routing structures 190 individually comprises tungsten.

In some embodiments, the second steps 162 of the sub-staircase structures 170 vertically descend (e.g., in the Z-direction) in a horizontal direction (e.g., in the Y-direction) substantially perpendicular to the conductive plate structures 187. In some embodiments, the conductive plate structures 187 are horizontally between (e.g., in the Y-direction) horizontally neighboring (e.g., in the Y-direction) staircase structures 175 that form an additional stadium structures (FIG. 1T).

With reference to FIG. 1W, in some embodiments, conductive routing regions 192 may be defined within horizontal boundaries (e.g., in the X-direction, in the Y-direction) of the isolation structures 148. The conductive routing regions 192 may be located horizontally between (e.g., in the X-direction) the staircase structures 175 and the vertical stacks of memory cells 186. Conductive interconnect and routing structures 194 (only one of which is illustrated in FIG. 1W for clarity and case of understanding the description) may be in electrical communication with the conductive contact structures 180 of within the staircase region 104 and may be in electrical communication with additional conductive contact structures 196 (only one of which is illustrated in FIG. 1W for clarity and case of understanding the description) in the conductive routing region 192.

The additional conductive contact structures 196 may be configured to be in electrical communication with circuitry of an additional microelectronic device (e.g., a microelectronic device structure) including circuitry, such as one or more of sub word line drivers, sense amplifier devices (e.g., equalization (EQ) amplifiers, isolation (ISO) amplifiers, NMOS sense amplifiers (NSAs), PMOS sense amplifiers (PSAs)), column decoders, multiplexer control logic devices, sense amplifier drivers, main word line driver devices, row decoder devices, and row select devices, may be attached to the microelectronic device 100. In some embodiments, the additional conductive contact structures 196 are configured to be in electrical communication with sub-word line drivers of an additional microelectronic device and configured to electrically couple the first conductive structures 134 to the sub-word line drivers of the additional microelectronic device.

Thus, in accordance with some embodiments of the disclosure, a microelectronic device comprises a memory array region comprising vertical stacks of dynamic random access memory (DRAM) cells, each of the DRAM cells comprising a storage device of a vertical stack of storage devices and a horizontally neighboring access device of a vertical stack of access devices, a staircase region substantially horizontally neighboring the memory array region in a first horizontal direction. The staircase region comprises a vertical stack of first conductive structures horizontally extending through the staircase region in the first horizontal direction, the first conductive structures in contact with the DRAM cells, and sub-staircase structures individually comprising second conductive structures in contact with the first conductive structures and horizontally extending from the first conductive structures in a second horizontal direction substantially perpendicular to the first horizontal direction, each of the sub-staircase structures individually comprising at least four steps, each step of the at least four steps defined at horizontal boundaries of one of the second conductive structures defining the step.

Thus, in accordance with some embodiments of the disclosure, a memory device comprises a memory array region comprising vertical stacks of memory cells comprising vertical stacks of access devices, vertical stacks of storage devices horizontally neighboring the vertical stacks of access devices, and a portion of a vertical stack structure comprising substantially linear first conductive structures horizontally extending through the vertical stacks of memory cells, the substantially linear first conductive structures neighboring the memory cells of the vertical stack of memory cells. The memory device further comprises a staircase region horizontally neighboring the memory array region, the staircase region comprising a staircase structure comprising an additional portion of the vertical stack structure horizontally extending in a first direction from the memory array region through the staircase region, and sub-staircase structures horizontally extending from the vertical stack structure in a second direction different than the first direction, the sub-staircase structures individually comprising second conductive structures defining at least three steps of the sub-staircase structures.

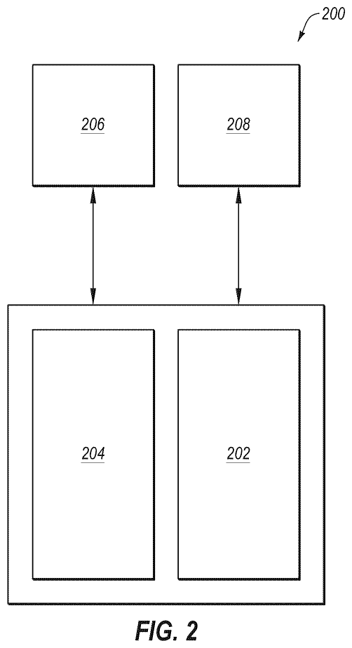

Microelectronic devices (e.g., the microelectronic device 100) of the disclosure may be included in embodiments of electronic systems of the disclosure. For example, FIG. 2 is a block diagram of an electronic system 200, in accordance with embodiments of the disclosure. The electronic system 200 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 200 includes at least one memory device 202. The memory device 202 may include, for example, an embodiment of a microelectronic device previously described herein (e.g., the microelectronic device 100 previously described with reference to FIG. 1A through FIG. 1X).

The electronic system 200 may further include at least one electronic signal processor device 204 (often referred to as a “microprocessor”). The electronic signal processor device 204 may, optionally, include an embodiment of one or more of a microelectronic device and a microelectronic device structure previously described herein. The electronic system 200 may further include one or more input devices 206 for inputting information into the electronic system 200 by a user, such as, for example, a mouse or other pointing device, a keyboard, a touchpad, a button, or a control panel. The electronic system 200 may further include one or more output devices 208 for outputting information (e.g., visual or audio output) to a user such as, for example, a monitor, a display, a printer, an audio output jack, a speaker, etc. In some embodiments, the input device 206 and the output device 208 may comprise a single touchscreen device that can be used both to input information to the electronic system 200 and to output visual information to a user. The input device 206 and the output device 208 may communicate electrically with one or more of the memory device 202 and the electronic signal processor device 204.

Accordingly, in at least some embodiments, an electronic device comprises an input device, an output device, a processor device operably coupled to the input device and the output device, and a microelectronic device operably coupled to the processor device and comprising a first array region comprising first vertical stacks of memory cells comprising first vertical stacks of access devices horizontally neighboring first vertical stacks of access devices, a second array region comprising second vertical stacks of memory cells comprising second vertical stacks of access devices horizontally neighboring second vertical stacks of access devices, a staircase region horizontally between the first array region and the second array region and comprising staircase structures. At least one of the staircase structures comprises a vertical stack comprising first conductive structures horizontally extending through the staircase region and through the first array region and the second array region, sub-staircase structures comprising second conductive structures horizontally extending in a horizontal direction extending away from the vertical stack, the sub-staircase structures individually comprising steps vertically descending in the horizontal direction extending away from the vertical stack and defined by edges of the second conductive structures, and conductive contact structures in contact with the second conductive structures in the horizontal direction extending away from the vertical stack and in a vertical direction.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
a memory array region comprising vertical stacks of dynamic random access memory (DRAM) cells, each of the DRAM cells comprising a storage device of a vertical stack of storage devices and a horizontally neighboring access device of a vertical stack of access devices;
a staircase region substantially horizontally neighboring the memory array region in a first horizontal direction, the staircase region comprising:
a vertical stack of first conductive structures horizontally extending through the staircase region in the first horizontal direction, the first conductive structures in contact with the DRAM cells; and
sub-staircase structures individually comprising second conductive structures in contact with the first conductive structures and horizontally extending from the first conductive structures in a second horizontal direction substantially perpendicular to the first horizontal direction, each of the sub-staircase structures individually comprising at least four steps, each step of the at least four steps defined at horizontal boundaries of one of the second conductive structures defining the step.

2. The microelectronic device of claim 1, further comprising conductive contact structures individually in contact with the second conductive structure of each step of the sub-staircase structures.

3. The microelectronic device of claim 2, wherein each conductive contact structure individually contacts the second conductive structure on a first surface of the conductive contact structure horizontally extending in the second horizontal direction and on a vertically extending second surface.

4. The microelectronic device of claim 1, further comprising additional sub-staircase structures horizontally spaced from the sub-staircase structures in the second horizontal direction, at least some of the steps of the additional sub-staircase structures vertically offset and within horizontal boundaries in the first horizontal direction of a corresponding step of the sub-staircase structures.

5. The microelectronic device of claim 4, further comprising further additional sub-staircase structures horizontally spaced from the sub-staircase structures in the second horizontal direction, at least some of the steps of the additional sub-staircase structures vertically aligned and within horizontal boundaries in the first horizontal direction of a corresponding step of the sub-staircase structures.

6. The microelectronic device of claim 1, further comprising an additional memory array region spaced from the memory array region in the first horizontal direction by the staircase region.

7. The microelectronic device of claim 6, wherein at least one of the second conductive structures is in contact with at least one of the first conductive structures in contact with some of the DRAM cells of the memory array region and some of additional DRAM cells of the additional memory array region.

8. The microelectronic device of claim 1, wherein a pitch of the sub-staircase structures in the first horizontal direction is about two times a pitch of the vertical stacks of DRAM cells in the first horizontal direction.

9. The microelectronic device of claim 1, further comprising a liner material overlying the at least four steps of each of the sub-staircase structures.

10. The microelectronic device of claim 9, wherein the liner material comprises aluminum oxide.

11. The microelectronic device of claim 1, further comprising a conductive routing region horizontally between the memory array region and the staircase region.

12. A memory device, comprising:
a memory array region comprising vertical stacks of memory cells comprising:
vertical stacks of access devices;
vertical stacks of storage devices horizontally neighboring the vertical stacks of access devices; and
a portion of a vertical stack structure comprising substantially linear first conductive structures horizontally extending through the vertical stacks of memory cells, the substantially linear first conductive structures neighboring the memory cells of the vertical stack of memory cells; and
a staircase region horizontally neighboring the memory array region, the staircase region comprising a staircase structure comprising:
an additional portion of the vertical stack structure horizontally extending in a first direction from the memory array region through the staircase region; and
sub-staircase structures horizontally extending from the vertical stack structure in a second direction different than the first direction, the sub-staircase structures individually comprising second conductive structures defining at least three steps of the sub-staircase structures.

13. The memory device of claim 12, wherein the additional portion of the vertical stack structure horizontally extends from the memory array region, through the staircase region, and to an additional memory array region.

14. The memory device of claim 12, wherein the sub-staircase structures individually comprise four steps vertically descending in the second direction.

15. The memory device of claim 12, wherein the second conductive structures of the sub-staircase structures vertically descend in the first direction in a direction from the memory array region towards the staircase region.

16. The memory device of claim 15, further comprising:
an additional portion of an additional stack structure comprising additional first conductive structures horizontally extending in the first direction from the memory array region through the staircase region; and
additional sub-staircase structures comprising additional second conductive structures horizontally extending from the additional first conductive structures in the second direction, the additional sub-staircase structures comprising a stadium structure in the first direction.

17. The memory device of claim 16, wherein a vertically lowermost step of the additional sub-staircase structures is horizontally offset in the first direction from a vertically lowermost step of the sub-staircase structures.

18. The memory device of claim 12, further comprising conductive contact structures individually in contact with the second conductive structures in the second direction and in a vertical direction.

19. An electronic system, comprising:
an input device;
an output device;
a processor device operably coupled to the input device and the output device; and
a microelectronic device coupled to the processor device and comprising:
a first array region comprising first vertical stacks of memory cells comprising first vertical stacks of access devices horizontally neighboring first vertical stacks of access devices;
a second array region comprising second vertical stacks of memory cells comprising second vertical stacks of access devices horizontally neighboring second vertical stacks of access devices;
a staircase region horizontally between the first array region and the second array region and comprising staircase structures, at least one of the staircase structures comprising:
a vertical stack comprising first conductive structures horizontally extending through the staircase region and through the first array region and the second array region;
sub-staircase structures comprising second conductive structures horizontally extending in a horizontal direction extending away from the vertical stack, the sub-staircase structures individually comprising steps vertically descending in the horizontal direction extending away from the vertical stack and defined by edges of the second conductive structures; and
conductive contact structures in contact with the second conductive structures in the horizontal direction extending away from the vertical stack and in a vertical direction.

20. The electronic system of claim 19, wherein each sub-staircase structure is defined by edges of four of the second conductive structures.
